(19) United States
(12) Patent Application Publication
(10) Pub. No.: US 2017/0226414 A1
(43) Pub. Date: Aug. 10, 2017

(54) FORMULATIONS, OPTICAL MATERIALS, PRODUCTS INCLUDING AN OPTICAL MATERIAL, AND METHODS

(71) Applicant: SAMSUNG ELECTRONICS CO., LTD., Suwon-si (KR)

(72) Inventors: Robert J. NICK, PEPPERELL, MA (US); Steven T. CHAO, ALLSTON, MA (US)

(21) Appl. No.: 15/426,787

(22) Filed: Feb. 7, 2017

Related U.S. Application Data
(60) Provisional application No. 62/292,449, filed on Feb. 8, 2016.

(51) Int. Cl. C09K 11/02; C09K 11/88; C08F 222/14; C08K 9/10; H01L 33/50

(52) U.S. Cl. CPC C09K 11/025; C08K 9/10; H01L 33/502; H01L 33/507; C08F 222/14; C09K 11/883; C08K 2201/001; C08K 2201/011; C08F 2222/145; B82Y 40/00

(57) ABSTRACT

The present invention includes formulations for use in preparing an optical material, optical materials, optical components and other products including optical materials, products including optical components, methods for improving various performance aspects of an optical material and optical components, and methods for purifying aliphatic methacrylate monomers and aliphatic dimethacrylates.

### TECHNICAL FIELD OF THE INVENTION

The present invention relates to technical fields of formulations, optical materials, products including an optical material, and methods.

### SUMMARY OF THE INVENTION

The present invention includes formulations for use in preparing an optical material, optical materials, optical components and other products including optical materials, products including optical components, methods for improving various performance aspects of an optical material and optical components, and methods for purifying aliphatic methacrylate monomers and aliphatic dimethacrylates.

In accordance with one aspect of the present invention, there is provided a formulation for use in preparing an optical material. The formulation comprises: a photopolymerizable host precursor material including a monomer comprising an aliphatic methacrylate monomer and a cross-linking agent, wherein the cross-linking agent is included in the photopolymerizable host precursor material in an amount from about 5 to about 13 mole percent based on the moles of cross-linking agent and monomer, the photopolymerizable host precursor material being included in the formulation in an amount of at least 50 weight percent of the formulation; and a photoluminescent material comprising quantum dots, the photoluminescent being included in the formulation in an amount from about 0.01 to about 15 weight percent of the formulation.

A formulation in accordance with the present invention preferably includes the cross-linking agent in an amount in the range from about 6 to about 8 mole percent based on the moles of cross-linking agent and monomer.

A formulation in accordance with the present invention can further include light scattering particles (also referred to herein as scattering particles). Scattering particles can be included in the formulation, for example, in an amount from about 0.01 to about 3 weight percent of the formulation. Scattering particles that are non-luminescent (e.g., that are not light emissive) can be preferred.

A formulation in accordance with the present invention can further include one or more emission stabilizers. An emission stabilizer can be included in the formulation, for example, in an amount from about 0.01 to about 15 weight percent of the formulation.

A formulation in accordance with the present invention can further include a rheology modifier. A rheology modifier can be included in the formulation in an amount, for example, from about 5 to about 12 weight percent of the formulation.

A formulation in accordance with the present invention can further include a photoinitiator. A photoinitiator can be included in the formulation, for example, in an amount from about 1 to about 5 weight percent of the formulation.

In accordance with a further aspect of the present invention, there is provided an optical material comprising a formulation within the scope of the present invention that has been polymerized.

In accordance with yet another aspect of the present invention, there is provided an optical material comprising: a host material comprising an aliphatic methacrylate polymer, the polymer being included in the composition in an amount of at least 50 weight percent of the optical material; and a photoluminescent material comprising quantum dots included in the host material, the photoluminescent material being included in the optical material in an amount from about 0.01 to about 15 weight percent of the optical material, the optical material being prepared from a formulation within the scope of the present invention, wherein the optical material has improved lumen maintenance.

In accordance with still a further aspect of the present invention, there is provided an optical component comprising an optically transparent structure in which an optical material within the scope of the present invention is included.

The optical component can include an optically transparent structure that hermetically contains the optical material.

In accordance with yet another aspect of the present invention, there is provided a method for improving the lumen maintenance of an optical material comprising an aliphatic methacrylate polymer, the method comprising: preparing a formulation comprising: a photopolymerizable host precursor material including a monomer comprising an aliphatic methacrylate monomer and a cross-linking agent, wherein the cross-linking agent is included in the photopolymerizable host precursor material in an amount from about 5 to about 13 mole percent based on the moles of cross-linking agent and monomer, the photopolymerizable host precursor material being included in the formulation in an amount of at least 50 weight percent of the formulation; and a photoluminescent material comprising quantum dots, the photoluminescent being included in the formulation in an amount from about 0.01 to about 15 weight percent of the formulation; wherein at least one of: (a) the aliphatic dimethacrylate has an absorbance at 325 nm less than or equal to 0.08 and an absorbance at 345 nm less than or equal to 0.03, and (b) the aliphatic methacrylate monomer has an absorbance at 345 nm less than or equal to 0.01 in the absence of an inhibitor, and polymerizing the formulation to form the optical material having improved lumen maintenance.

The method can further comprise including the formulation included in an optical component including an optically transparent structure prior to polymerizing the formulation.

In accordance with a still further aspect of the present invention, there is provided a method for reducing the occurrence of visible voids in an optical material including an aliphatic methacrylate polymer and quantum dots after exposure to a temperature of −30° C. for 1000 hours, the method comprising: polymerizing a formulation comprising: a photopolymerizable host precursor material including a monomer comprising an aliphatic methacrylate monomer and a cross-linking agent, wherein the cross-linking agent is included in the photopolymerizable host precursor material in an amount from about 5 to about 13 mole percent based on the moles of cross-linking agent and monomer, the photopolymerizable host precursor material being included in the formulation in an amount of at least 50 weight percent of the formulation; and a photoluminescent material comprising quantum dots, the photoluminescent being included in the formulation in an amount from about 0.01 to about 15 weight percent of the formulation, wherein at least one of: the aliphatic dimethacrylate has an absorbance at 325 nm less than or equal to 0.08 and an absorbance at 345 nm less than or equal to 0.03, and (b) the aliphatic methacrylate monomer has an absorbance at 345 nm less than or equal to 0.01 in the absence of an inhibitor; and polymerizing the formulation.

The method can provide an optical material that has reduced occurrence of visible voids within 7 days after exposure to a temperature −30° C. for I 000 hours.

The method can further comprise including the formulation in an optical component including an optically transparent structure prior to polymerizing the formulation.

In accordance with a still further aspect of the present invention, there is provided a method for reducing the occurrence of visible voids in an optical material including an aliphatic methacrylate polymer and quantum dots contained within a sealed optically transparent structure after exposure of the sealed structure to a temperature of −30° C. for 1000 hours, the method comprising: polymerizing a formulation comprising: a photopolymerizable host precursor material including a monomer comprising an aliphatic methacrylate monomer and a cross-linking agent, wherein the cross-linking agent is included in the photopolymerizable host precursor material in an amount from about 5 to about 13 mole percent based on the moles of cross-linking agent and monomer, the photopolymerizable host precursor material being included in the formulation in an amount of at least 50 weight percent of the formulation; and a photoluminescent material comprising quantum dots, the photoluminescent being included in the formulation in an amount from about 0.01 to about 15 weight percent of the formulation, wherein at least one of: the aliphatic dimethacrylate has an absorbance at 325 nm less than or equal to 0.08 and an absorbance at 345 nm less than or equal to 0.03, and (b) the aliphatic methacrylate monomer has an absorbance at 345 nm less than or equal to 0.01 in the absence of an inhibitor; and polymerizing the formulation.

The method can provide an optical component including an optical material that has reduced occurrence of visible voids within 7 days after exposure to a temperature −30° C. for 1000 hours.

In accordance with another aspect of the present invention, there is provided a method for forming an optical material comprising an aliphatic methacrylate polymer and a photoluminescent material comprising quantum dots with improved ductility, the method comprising: preparing a formulation comprising: a photopolymerizable host precursor material including a monomer comprising an aliphatic methacrylate monomer and a cross-linking agent, wherein the cross-linking agent is included in the photopolymerizable host precursor material in an amount from about 5 to about 13 mole percent based on the moles of cross-linking agent and monomer, the photopolymerizable host precursor material being included in the formulation in an amount of at least 50 weight percent of the formulation, the photoluminescent material comprising quantum dots, the photoluminescent being included in the formulation in an amount from about 0.01 to about 15 weight percent of the formulation, wherein at least one of: (a) the aliphatic dimethacrylate has an absorbance at 325 nm less than or equal to 0.08 and an absorbance at 345 nm less than or equal to 0.03, and (b) the aliphatic methacrylate monomer has an absorbance at 345 nm less than or equal to 0.01 in the absence of an inhibitor, and polymerizing the formulation to form the optical material whereby improved ductility is demonstrated by the optical material exhibiting fewer visible voids having a size>0.5 mm within 7 days after exposure to a temperature −30° C. for 1000 hours compared to a comparative optical material prepared from a comparative formulation that is the same in all respects except that it includes a cross-linking agent content in an amount in a range of about 13-14 mole percent based on the moles of cross-linking agent and monomer and the comparative formulation does not include at least one of (a) and (b) after exposure to a temperature −30° C. for 1000 hours.

In accordance with a still further aspect of the present invention, there is provided a light-emitting device comprising a light-emitting element and an optical material arranged to receive and convert at least a portion of light emitted by the light emitting element from a first emission wavelength to one or more predetermined wavelengths, wherein the optical material comprises an optical material within the scope of the present invention.

In accordance with a still further aspect of the present invention, there is provided a display comprising an optical material, wherein the optical material comprises an optical material within the scope of the present invention.

In accordance with a still further aspect of the present invention, there is provided a display including a backlight member including a plurality of light-emitting diodes and an optical material arranged to receive and convert at least a portion of light emitted by at least a portion of the light-emitting diodes from a first emission wavelength to one or more predetermined wavelengths, wherein the optical material comprises an optical material within the scope of the present invention.

In accordance with a still further aspect of the present invention, there is provided a device comprising an optical material within the scope of the present invention.

In accordance with a still further aspect of the present invention, there is provided a light-emitting device comprising a light-emitting element and an optical component within the scope of the present invention, the optical component being arranged to receive and convert at least a portion of light emitted by the light emitting element from a first emission wavelength to one or more predetermined wavelengths.

In accordance with a still further aspect of the present invention, there is provided a display comprising an optical component within the scope of the present invention.

In accordance with a still further aspect of the present invention, there is provided a display including a backlight member including a plurality of light-emitting diodes and an optical component within the scope of the present invention arranged to receive and convert at least a portion of light emitted by at least a portion of the light-emitting diodes from a first emission wavelength to one or more predetermined wavelengths.

In accordance with a still further aspect of the present invention, there is provided a device comprising an optical component within the scope of the present invention.

In accordance with a still further aspect of the present invention, there is provided a method for purifying an aliphatic methacrylate monomer comprising: (a) stirring a mixture including an aliphatic methacrylate monomer including at least one impurity with an activated adsorbent powder to purify the aliphatic methacrylate monomer by adsorption of at least a portion the at least one impurity by the activated adsorbent powder, (b) filtering the mixture to remove the used activated adsorbent powder and collect the purified aliphatic methacrylate monomer, and (c) repeating steps (a) and (b) until the aliphatic methacrylate monomer has an absorbance at 345 nm less than or equal to 0.01, wherein the method is carried out in the absence of a polymerization inhibitor.

The method can further comprise repeating steps (a) and (b) until no change is observed in the absorption spectrum of the collected purified aliphatic methacrylate monomer.

In accordance with another aspect of the present invention, there is provided a method for purifying an aliphatic dimethacrylate comprising: (a) stirring a mixture including an aliphatic dimethacrylate including at least one impurity with an activated adsorbent powder to purify the aliphatic dimethacrylate by adsorption of at least a portion the at least one impurity by the activated adsorbent powder, (b) filtering the mixture to remove the used activated adsorbent powder and collect the purified aliphatic dimethacrylate, and (c) repeating steps (a) and (b) until the collected purified aliphatic dimethacrylate has an absorbance at 325 nm less than or equal to 0.08 and an absorbance at 345 nm less than or equal to 0.03.

The method can further comprise repeating steps (a) and (b) until no change is observed in the absorption spectrum of the collected purified aliphatic dimethacrylate

The foregoing, and other aspects and embodiments described herein all constitute embodiments of the present invention.

It should be appreciated by those persons having ordinary skill in the art(s) to which the present invention relates that any of the features described herein in respect of any particular aspect and/or embodiment of the present invention can be combined with one or more of any of the other features of any other aspects and/or embodiments of the present invention described herein, with modifications as appropriate to ensure compatibility of the combinations. Such combinations are considered to be part of the present invention contemplated by this disclosure.

It is to be understood that both the foregoing general description and the following detailed description are exemplary and explanatory only and are not restrictive of the invention as claimed. Other embodiments will be apparent to those skilled in the art from consideration of the specification and practice of the invention disclosed herein.

### BRIEF DESCRIPTION OF THE DRAWINGS

In the drawings, the patent or application file contains at least one drawing executed in color. Copies of this patent or patent application publication with color drawing(s) will be provided by the Office upon request and payment of the necessary fee.

FIG. 1 graphically shows normalized lumen output as a function of time for optical components including optical materials prepared from the designated formulations described in the corresponding Examples when tested under 445 nm blue light at 10 W/cm² flux condition and 105° C. thermal condition.

FIG. 2 graphically shows normalized lumen output as a function of time for optical components including optical materials prepared from the designated formulations described in the corresponding Examples when tested under 445 nm blue light at 10 W/cm² flux condition and 105° C. thermal condition.

FIG. 3 graphically shows normalized lumen output as a function of time for optical components including optical materials prepared from the designated formulations described in the corresponding Examples when tested under 445 nm blue light at 10 W/cm² flux condition and 105° C. thermal condition.

FIG. 4 graphically depicts normalized lumens as a function of time for optical components including optical materials prepared from the designated formulations described in the corresponding Examples when tested under 445 nm blue light at 810 mW/LED flux condition and 97° C. thermal condition.

FIGS. 5A-5C graphically depict normalized lumens and CIE (x,y) shift over time for optical components including optical materials prepared from the designated formulations described in the corresponding Examples.

FIGS. 6A and 6B graphically depict peak wavelength shift over time for optical components including optical materials prepared from the designated formulations described in the corresponding Examples.

FIGS. 7A-7C graphically depict red, green, and blue normalized intensity over time for optical components optical materials prepared from the designated formulations described in the corresponding Examples.

FIG. 8 graphically depicts normalized lumen output as a function of time for optical components including optical materials prepared from the designated formulations described in the corresponding Examples when tested under 445 nm blue light at 10 W/cm² flux condition and 105° C. thermal condition.

FIGS. 9A-9C graphically depict normalized lumens and CIE (x,y) shift over time for optical components including optical materials prepared from the designated formulations described in the corresponding Examples.

FIGS. 10A and 10B graphically depict peak wavelength shift over time for optical components including optical materials prepared from the designated formulations described in the corresponding Examples.

FIGS. 11A-11C graphically depicts red, green, and blue normalized intensity over time for optical components including optical materials prepared from the designated formulations described in the Examples.

FIG. 12 shows the absorption spectrum of commercial D3DMA as received.

FIG. 13 shows absorption spectra for D3DMA purified by different embodiments of a method described herein.

FIG. 14 shows absorption spectra for D3DMA purified by different embodiments of a method described herein.

FIG. 15 shows absorption spectra for D3DMA purified by different embodiments of a method described herein.

FIG. 16 shows absorption spectra for LMA purified by different embodiments of a method described herein

The attached figures are simplified representations presented for purposes of illustration only; the actual structures may differ in numerous respects, particularly including the relative scale of the articles depicted and aspects thereof.

For a better understanding to the present invention, together with other advantages and capabilities thereof, reference is made to the following disclosure and appended claims in connection with the above-described drawings.

### DETAILED DESCRIPTION OF THE INVENTION

Various aspects and embodiments of the present inventions will be further described in the following detailed description.

The present invention includes formulations for use in preparing an optical material, optical materials, optical components and other products including optical materials, products including optical components, methods for improving various performance aspects of an optical material and optical components, and methods for purifying aliphatic methacrylate monomers and aliphatic dimethacrylates.

In accordance with one aspect of the present invention, there is provided a formulation for use in preparing an optical material, the formulation comprising: a photopolymerizable host precursor material including a monomer comprising an aliphatic methacrylate monomer and a cross-linking agent, wherein the cross-linking agent is included in the photopolymerizable host precursor material in an amount from about 5 to about 13 mole percent based on the moles of cross-linking agent and monomer, the photopolymerizable host precursor material being included in the formulation in an amount of at least 50 weight percent of the formulation; and a photoluminescent material comprising quantum dots, the photoluminescent being included in the formulation in an amount from about 0.01 to about 15 weight percent of the formulation.

A photopolymerizable host precursor material including a monomer comprising an aliphatic methacrylate monomer, in its non-polymerized fluid form, can facilitate disposing or including the formulation on or in an optical structure. For example, a formulation in the form of a fluid can be placed within an optical structure comprising a tube or other container. The optical structure can additionally be sealed or closed to contain the formulation or resulting optical material within the structure. The formulation or resulting optical material can further be hermetically contained within a sealed or closed structure to avoid oxygen from being within or entering the structure. Alternatively, the formulation can be disposed between opposing plates and/or sheets. The perimeter edges of such “sandwich” arrangement can further be hermetically sealed. After the formulation is disposed within or on an optical structure, formulation can be subjected to light of sufficient intensity and for a period of time sufficient to polymerize the formulation, preferably in the absence of oxygen. In certain embodiments, for example, the period of time can range between about 10 seconds to about 6 minutes or between about 1 minute to about 6 minutes. According to one embodiment, the period of time is sufficiently short to avoid agglomeration of the quantum dots prior to formation of an optical material by polymerization of a formulation. Agglomeration can result in FRET and subsequent loss of photoluminescent performance.

For shelf life purposes, an aliphatic methacrylate monomer typically includes <500 (±50) ppm inhibitor (e.g., hydroquinone monomethyl ether (MeHQ)) to prevent premature polymerization of the monomer.

An aliphatic methacrylate monomer included in a photopolymerizable host precursor material included in a formulation of the present invention preferably has an absorbance at 345 nm less than or equal to 0.01 (when measured in the absence of an inhibitor).

An aliphatic methacrylate monomer having an absorbance at 345 nm less than or equal to 0.01 can be prepared, for example, by treating the monomer (not including a polymerization inhibitor, e.g., to which an inhibitor has not been added or from which it has been removed) with an adsorbent powder or other particulate purifying solid until an absorbance spectrum including such absorption feature is obtained. Other purification methods can also be used.

Such inhibitor is beneficially added after the desired absorbance spectrum is obtained for the monomer. (The addition of an inhibitor after such purification can mask the desired feature in an absorbance spectrum measured after the addition of the inhibitor.)

A photopolymerizable host precursor material can also comprise a combination of the aliphatic methacrylate monomer with one or more additional monomers. A photopolymerizable host precursor material preferably avoids, resists or inhibits yellowing when in the form of a polymer. A host material prepared from a photopolymerizable host precursor material is at least partially transparent, and preferably fully transparent, to preselected wavelengths of light.

Examples of additional polymerizable monomers for further inclusion with aliphatic methacrylate monomer in a photopolymerizable host material include, but are not limited to, other methacrylate-containing monomers, Ebecryl 150 (Cytec), CD590 (Cytec) and the like.

A photopolymerizable host precursor material can be present in the formulation in an amount greater than 50 weight percent. Examples include amounts in a range greater than 50 to about 99.5 weight percent, greater than 50 to about 98 weight percent, greater than 50 to about 95 weight percent, from about 80 to about 99.5 weight percent, from about 90 to about 99.95 weight percent, from about 95 to about 99.95 weight percent. Other amounts outside these examples may also be determined to be useful or desirable.

A photopolymerizable host precursor material included in a formulation in accordance with the present invention also includes a cross-linking agent.

A cross-linking agent can be present in the polymerizable formulation in an amount from about 5 to about 13 mole percent based on the moles of cross-linking agent and monomer. In certain embodiments, a cross-linking agent can be present in the polymerizable formulation in an amount from about 6 to about 8 mole percent based on the moles of cross-linking agent and monomer. A cross-linking agent can comprise a mixture of cross-linking agents. Examples of suitable cross-linking agents include aliphatic dimethacrylates, ethylene glycol dimethacrylate Ebecryl 150 and the like. Other amounts within these ranges can also be used.

A cross-linking agent comprising an aliphatic dimethacrylate is preferred.

An aliphatic dimethacrylate included as a cross-linking agent in a formulation of the present invention preferably has an absorbance at 325 nm less than or equal to 0.08 and an absorbance at 345 nm less than or equal to 0.03.

An aliphatic dimethacrylate having an absorbance at 325 nm less than or equal to 0.08 and an absorbance at 345 nm less than or equal to 0.03 can be prepared, for example, by treating the aliphatic dimethacrylate with an adsorbent powder or other particulate purifying solid until an absorbance spectrum including such absorption features is obtained. Other purification methods can also be used.

A photoluminescent material included in a formulation in accordance with the present invention comprises quantum dots.

A photoluminescent material comprising quantum dots included in a formulation or optical material within the scope of the invention is preferably in a range from about 0.01 weight percent to about 15 weight percent, and more preferably in a range from about 0.1 weight percent to about 5 weight percent and any value or range in between whether overlapping or not. Other amounts outside these examples may also be determined to be useful or desirable.

The amount of quantum dots included in a formulation or optical material can vary within such range depending upon the application and the form in which the photoluminescent material is included (e.g., film, optics (e.g., capillary), encapsulated film, etc.), which can be chosen based on the particular end application.

A photoluminescent material included in a formulation can include a combination of quantum dots that emit light at different predetermined wavelengths. For example, a mixture of quantum dots capable of emitting red light and quantum dots capable of emitting green light. Inclusion of quantum dots capable of emitting other color light may also be desirable based on the particular end-use application in which the formulation or optical material may be used. In certain applications, including quantum dots in the photoluminescent material that emit light of a single color may be desirable.

The ratio of quantum dots used in a formulation or optical material is determined by the desired emission peaks of the quantum dots used.

Quantum dots or semiconductor nanocrystals are nanometer sized semiconductor particles that can have optical properties arising from quantum confinement. Quantum dots can have various shapes, including, but not limited to, sphere, rod, disk, other shapes, and mixtures of various shaped particles. The particular composition(s), structure, and/or size of a quantum dot can be selected to achieve the desired wavelength of light to be emitted from the quantum dot upon stimulation with a particular excitation source. In essence, quantum dots may be tuned to emit light across the visible spectrum by changing their size. (Quantum dot is also abbreviated herein as “QD”).

A quantum dot can comprise one or more. semiconductor materials. Examples of semiconductor materials that can be included in a quantum dot (including, e.g., semiconductor nanocrystal) include, but are not limited to, a Group IV. element, a Group II-VI compound, a Group 11-V compound, a Group III-VI compound, a Group III-V compound, a Group IV-VI compound, a Group compound, a Group 11-IV-VI compound, a Group 11-IV-V compound, an alloy including any of the foregoing, and/or a mixture including any of the foregoing, including ternary and quaternary mixtures or alloys. A non-limiting list of examples include ZnO, ZnS, ZnSe, ZnTe, CdO, CdS, CdSe, CdTe, MgS, MgSe, GaAs, GaN, GaP, GaSe, GaSb, HgO, HgS, HgSe, HgTe, InAs, InN, InP, InSb, AlAs, AlN, AIP, AlSb, TIN, TIP, TlAs, TISb, PbO, PbS, PbSe, PbTe, Ge, Si, an alloy including any of the foregoing, and/or a mixture including any of the foregoing, including ternary and quaternary mixtures or alloys. Preferably a quantum dot is not doped with an activator element.

In certain embodiments, quantum dots can comprise a core comprising one or more inorganic semiconductor materials and a shell comprising one or more inorganic semiconductor materials, wherein the shell is disposed over at least a portion, and preferably all, of the outer surface of the core. A quantum dot including a core and shell is also referred to as a “core/shell” structure.

In a core/shell quantum dot, the shell or overcoating may comprise one or more layers. The overcoating can comprise at least one semiconductor material which is the same as or different from the composition of the core. Preferably, the overcoating has a thickness from about one to about ten monolayers. An overcoating can also have a thickness greater than ten monolayers. In certain embodiments, more than one overcoating can be included on a core. By adjusting the temperature of the reaction mixture during overcoating and monitoring the absorption spectrum of the core, overcoated materials having high emission quantum efficiencies and narrow size distributions can be obtained.

In certain embodiments, the surrounding “shell” material can have a band gap greater than the band gap of the core material. In certain other embodiments, the surrounding shell material can have a band gap less than the band gap of the core material.

In certain embodiments, the shell can be chosen so as to have an atomic spacing close to that of the “core” substrate. In certain other embodiments, the shell and core materials can have the same crystal structure.

Methods of making quantum dots are known. One example of a method of manufacturing a quantum dot (including, for example, but not limited to, a semiconductor nanocrystal) is a colloidal growth process. Colloidal growth occurs by injection an M donor and an X donor into a hot coordinating solvent. One example of a preferred method for preparing monodisperse quantum dots comprises pyrolysis of organometallic reagents, such as dimethyl cadmium, injected into a hot, coordinating solvent. This permits discrete nucleation and results in the controlled growth of macroscopic quantities of quantum dots. The injection produces a nucleus that can be grown in a controlled manner to form a quantum dot. The reaction mixture can be gently heated to grow and anneal the quantum dot. Both the average size and the size distribution of the quantum dots in a sample are dependent on the growth temperature. The growth temperature for maintaining steady growth increases with increasing average crystal size. Resulting quantum dots are members of a population of quantum dots. As a result of the discrete nucleation and controlled growth, the population of quantum dots that can be obtained has a narrow, monodisperse distribution of diameters. The monodisperse distribution of diameters can also be referred to as a “size”. Preferably, a monodisperse population of particles includes a population of particles wherein at least about 60% of the particles in the population fall within a specified particle size range. A population of monodisperse particles preferably deviate less than 15% rms (root-mean-square) in diameter and more preferably less than 10% rms and most preferably less than 5%.

Quantum dots preferably have ligands attached thereto. According to one aspect, quantum dots within the scope of the present invention include green CdSe quantum dots having oleic acid ligands and red CdSe quantum dots having oleic acid ligands. Alternatively, or in addition, octadecylphosphonic acid (“ODPA”) ligands may be used instead of oleic acid ligands. The ligands promote solubility of the quantum dots in the polymerizable composition which allows higher loadings without agglomeration which can lead to red shifting.

Ligands can be derived from a coordinating solvent that may be included in the reaction mixture during the growth process. Ligands can be added to the reaction mixture. Ligands can be derived from a reagent or precursor included in the reaction mixture for synthesizing the quantum dots. Ligands can be exchanged with ligands on the surface of a quantum dot. In certain embodiments, quantum dots can include more than one type of ligand attached to an outer surface.

A quantum dot surface that includes ligands derived from the growth process or otherwise can be modified by repeated exposure to an excess of a competing ligand group (including, e.g., but not limited to, a coordinating group) to form an overlayer. For example, a dispersion of the capped quantum dots can be treated with a coordinating organic compound, such as pyridine, to produce crystallites which disperse readily in pyridine, methanol, and aromatics but no longer disperse in aliphatic solvents. Such a surface exchange process can be carried out with any compound capable of coordinating to or bonding with the outer surface of the nanoparticle, including, for example, but not limited to, phosphines, thiols, amines and phosphates.

Suitable coordinating ligands can be purchased commercially or prepared by ordinary synthetic organic techniques, for example, as described in J. March, Advanced Organic Chemistry, which is incorporated herein by reference in its entirety.

The emission from a quantum dot capable of emitting light can be a narrow Gaussian emission band that can be tuned through the complete wavelength range of the ultraviolet, visible, or infra-red regions of the spectrum by varying the size of the quantum dot, the composition of the quantum dot, or both. The narrow size distribution of a population of quantum dots capable of emitting light can result in emission of light in a narrow spectral range. Spectral emissions in a narrow range of no greater than about 75 nm, preferably no greater than about 60 nm, more preferably no greater than about 40 nm, and most preferably no greater than about 30 nm full width at half maximum (FWHM) for such quantum dots that emit in the visible can be observed. The breadth of the emission decreases as the dispersity of the light-emitting quantum dot diameters decreases.

Quantum dots can have emission quantum efficiencies such as between 0% to greater than 95%, for example in solution, such as greater than 10%, 20%, 30%, 40%, 50%, 60%, 70%, 80%, or 90%.

The quantum dots used in a formulation or optical material taught herein are selected based on the desired peal<emission wavelength or combinations of wavelengths desired for the particular intend end-use application for the formulation or optical material. When quantum dots that emit light with peak emission wavelengths that differ from that of other quantum dots included in a particular embodiments, the amounts of each are selected based on the desired light out-put. Such determination can be readily made by the person of ordinary sldll in the relevant art. For example, the ratio of quantum dots with different peak emissions that are used in an optical material is determined by the emission peaks of the quantum dots used.

Additional information relating to quantum dots that may be helpful can be found, for example, in: U.S. Publication No. 20150014629 A 1, published 15 Jan. 2015, of Breen, et al., entitled “Methods For Coating Semiconductor Nanocrystals”; U.S. Publication No. 20150013589 A 1, published 15 Jan. 2015, of Liu, et al., entitled “Method of Making Quantum Dots”; U.S. Publication No. 20150021551 A 1, published 22 Jan. 2015, of Breen, et al., entitled “Methods For Coating Semiconductor Nanocrystals”; and U.S. Publication No. 20150014586 A1, published 15 Jan. 2015, of Liu, et al., entitled “Method of Making Quantum Dots”, each of which is hereby incorporated herein by reference in its entirety.

Optionally, a photoluminescent material can further include one or more phosphors in addition to the quantum dots.

A formulation in accordance with the present invention can further include scattering particles, a rheology modifiers, photoinitiators, and/or emission stabilizers.

A formulation in accordance with the present invention can include scattering particles. Scattering particles, which are preferably non-luminescent, can be included in the formulation in an amount, for example, from about 0.01 to about 3 weight percent, including, for example, from about 0.05 weight percent to about 1.0 weight percent. Other amounts outside these examples may also be determined to be useful or desirable. Light interacting with scattering particles will be scattered within a specific range of directions according to the size and index of refraction of the particles. Scattering particles can increase absorption pathlength of excitation light used to excite the photoluminescent material included in the in an optical material formed from the formulation and aid in out-coupling of light down-converted by the photoluminescent material. Inclusion of non-light emissive or non-luminescent scattering particles in an optical material prepared from the formulation also provide better color uniformity and also enable the use of lower photoluminescent material concentrations. It is to be appreciated that there is a tradeoff between improved color uniformity and lower efficiency due to the scattering process. Scattering particles (which may also be referred to herein as scatterers) may be formed of sub-wavelength size particles with significantly higher index of refraction than that of the polymerized host precursor material, such of Ti02, alumina, barium sulfate, PTFE, barium titanate, zinc oxide, antimony oxide, and the like, or suitable combinations. Other suitable materials for scatterers will become readily apparent to those skilled in the art, given the benefit of this disclosure. In certain embodiments, a scatterer amount of about 0.15 weight percent can be preferred.

Selection of the size and size distribution of the scatterers can be readily determined by those skilled in the art, given the benefit of this disclosure. The size and size distribution can be based upon the refractive index mismatch of the scattering particle and the host material in which the light scatterers are to be dispersed, and the preselected wavelength(s) to be scattered according to light scattering theory, e.g., Rayleigh or Mie scattering theory. The surface of the scattering particle may further be treated to improve dispersability and stability in the host material. In one embodiment, the scattering particle comprises Ti0₂ (R902+ from DuPont) having a 0.405 μm median particle size in a concentration in a range from about 0.01 to about 1% by weight.

A formulation in accordance with the present invention can further include a rheology modifier. A rheology modifier can be present in a formulation in an amount, for example, between about Sweight percent to about 12 weight percent. Other amounts outside these examples may also be determined to be useful or desirable. A rheology modifier can comprise a mixture of rheology modifiers. Rheology modifiers or thixotropes can lower the shrinkage of a polymer or resin and help prevent cracking. Hydrophobic rheology modifiers disperse more easily and build viscosity at higher loadings allowing for more filler content and Jess shrinkage to the point where the formulation becomes too viscous to fill the tube. Rheology modifiers such as fumed silica also provide higher EQE and help to prevent settling of scattering particles (e.g., Ti0₂) (when included in the formulation) before polymerization has taken place. Suitable rheology modifiers (thixotropes) include fumed silica commercially available from Cabot Corporation such as TS-720 treated fumed silica, treated silica commercially available from Cabot Corporation such as TS720, TSSOO, TS530, TS610 and hydrophilic silica such as MS and EHS commercially available from Cabot Corporation.

A formulation in accordance with the present invention can include a photoinitiator. A photoinitiators can be included in the polymerizable formulation in an amount, for example, between about I weight percent to about 5 weight percent. A photoinitiator can comprise a mixture of photoinitiators. Other amounts outside this range may also be determined to be useful or desirable. Photoinitiators generally help to sensitize the polymerizable composition to UV light for photopolymerization. Suitable photoinitiators include Irgacure 2022, KT0-46 (Lambert), Esacure 1 (Lambert) and the like.

A formulation or optical material in accordance with the present invention can further include one or more emission stabilizers. An emission stabilizer can be included in the formulation, for example, in an amount from about 0.01 to about 15 weight percent of the formulation. If more than one emission stabilizer is included, each can be included in the formulation, for example, in an amount from about 0.01 to about 15 weight percent of the formulation. Other amounts outside these examples may also be determined to be useful or desirable.

Inclusion of an emission stabilizer can improve or enhance the stability of at least one emissive property of the quantum dots in the composition against degradation compared to a composition that is the same in all respects except that it does not include the emission stabilizer. Examples of such emissive properties include, by way of example only, lumen output, lumen stability, color point (e.g., CIEx, CIEy) stability, wavelength stability, FWHM of the major peak emission, absorption, solid state EQE, and quantum dot emission efficiency.

Preferably, an emission stabilizer is included in the composition in an amount effective to improve or enhance at least one emissive property of the quantum dots in the composition against degradation.

Preferred emission stabilizers include K₂DP and TOPO. Additional information relating to emission stabilizers and examples of other emission stabilizers for use with quantum dots are described in U.S. Publication No. 20150021521 A 1, published 22 Jan. 2015, of Nick, et al., entitled “Quantum Dot-Containing Compositions Including An Emission Stabilizer, Products Including Same, and Method”, which is hereby incorporated herein by reference.

Other additives may be further included in the formulation based upon the intended end-use application of the formulation or optical material.

In accordance with another aspect of the present invention, there is provided an optical material prepared from a formulation taught herein that has been polymerized. The formulation from which the optical material is prepared can preferably include at least one of a cross-linking agent comprising an aliphatic dimethacrylate having an absorbance at 325 nm less than or equal to 0.08 and an absorbance at 345 nm less than or equal to 0.03, and an aliphatic methacrylate monomer has an absorbance at 345 nm less than or equal to 0.01 in the absence of an inhibitor. More preferably, the optical material is prepared from a formulation described herein that includes both a cross-linking agent comprising an aliphatic dimethacrylate, which preferably has an absorbance at 325 nm less than or equal to 0.08 and an absorbance at 345 nm less than or equal to 0.03, and an aliphatic methacrylate monomer, which preferably has an absorbance at 345 nm less than or equal to 0.01 (when measured in the absence of an inhibitor.)

Inclusion of the cross-linking agent in an amount in a range from about 6 to about 8 mole percent of the moles of the cross-linking agent and monomer included in the photopolymerizable host precursor material included in the formulation can also be advantageous, as seen in the Examples below.

Preferably, the formulation is polymerized by exposing the formulation to light energy (e.g., UV light) to polymerize the photopolymerizable precursor monomer in which the other components are distributed or dispersed. Preferably, the other components included in the formulation are uniformly or substantially uniformly dispersed in the resulting polymer host material.

In accordance with another aspect of the present invention, there is provided an optical material comprising: a host material comprising an aliphatic methacrylate polymer, the polymer being included in the composition in an amount of at least 50 weight percent of the optical material; and a photoluminescent material comprising quantum dots included in the host material, the photoluminescent being included in the optical material in an amount from about 0.01 to about 15 weight percent of the optical material, wherein the optical material is prepared from a formulation within the scope of the present invention, wherein the optical material has improved lumen maintenance.

A lumen maintenance improvement under light and thermal conditions is demonstrated in the Examples and Figures. The examples show an optical material comprising: a host material comprising an aliphatic methacrylate polymer, the polymer being included in the composition in an amount of at least 50 weight percent of the optical material; and a photoluminescent material comprising quantum dots included in the host material, the photoluminescent being included in the optical material in an amount from about 0.01 to about 15 weight percent of the optical material that is prepared from a formulation within the scope of the present invention can have improved lumen maintenance under 445 nm blue light at 10 W/cm² flux condition and 105° C. thermal condition compared to on optical material prepared from a formulation that is the same in all respects except that it includes a cross-linking agent content in an amount in a range of about 13-14 mole percent based on the moles of cross-linking agent and monomer when tested under the same conditions.

The examples also show an optical material comprising: a host material comprising an aliphatic methacrylate polymer, the polymer being included in the composition in an amount of at least 50 weight percent of the optical material; and a photoluminescent material comprising quantum dots included in the host material, the photoluminescent being included in the optical material in an amount from about 0.01 to about 15 weight percent of the optical material that is prepared from a formulation within the scope of the present invention can have improved lumen maintenance under 445 nm blue light at 810 mW/LED flux condition and 97° C. thermal condition compared to on optical material prepared from a formulation that is the same in all respects except that it includes a cross-linking agent content in an amount in a range of about 13-14 mole percent based on the moles of cross-linking agent and monomer when tested under the same conditions.

As shown in the examples, a lumen maintenance improvement can be demonstrated by L₇₀ of an optical material or optical component within the scope of the present invention being higher than L70 of a comparative optical material or optical component including an optical material, where the comparative optical material is prepared from a formulation that is the same in all respects as that used to prepare the optical material or optical component within the scope of the present invention except that the comparative formulation used to prepare the comparative optical material includes a cross-linking agent content in an amount in a range of about 13-14 mole percent based on the moles of cross-linking agent and monomer, wherein L₇₀ is the time required for a material to lose 70% of its initial luminance (measured at t=O) under the given set of flux and thermal conditions.

The host material can comprise a combination of the aliphatic methacrylate polymer with one or more additional polymers. The host precursor material preferably avoids, resists or inhibits yellowing. The host material is at least partially transparent, and preferably fully transparent, to preselected wavelengths of light.

Examples of additional polymers for inclusion with aliphatic methacrylate polymer in a host material include, but are not limited to, other methacrylate-containing polymers and polymers resulting from Ebecryl 150 (Cytec), CD590 (Cytec) and the like.

A host material can be present in the optical material in an amount of at least 50 weight percent. Examples include amounts in a range greater than 50 to about 99.5 weight percent, greater than 50 to about 98 weight percent, greater than 50 to about 95 weight percent, from about 60 to about 99.5 weight percent, from about 70 to about 60 weight percent, from about 95 to about 99.95 weight percent. Other amounts outside these ranges may also be determined to be useful or desirable.

A photoluminescent material comprising quantum dots included in the optical material is preferably in a range from about 0.01 weight percent to about 15 weight percent, and more preferably in a range from about 0.1 weight percent to about 5 weight percent and any value or range in between whether overlapping or not. Other amounts outside these examples may also be determined to be useful or desirable.

The amount of quantum dots included in a formulation or optical material can vary within such ranges depending upon the end-use application in which the photoluminescent material will be used and can be chosen based on the particular end application.

Photoluminescent materials that can be included in an optical material include those discussed above, in the patent documents incorporated herein by reference, and elsewhere in this application.

An optical material can further include scattering particles. Such scattering particles can be included in the optical material in an amount, for example, from about 0.01 to about 3 weight percent of the optical material. Scattering particles that are non-luminescent (e.g., that are not light emissive) can be preferred. Other amounts outside this range may also be determined to be useful or desirable. Further information concerning scattering and scattering particles is provided elsewhere herein.

An optical material can include one or more emission stabilizers. Each emission stabilizer can be included in the optical material, for example, in an amount, for example, from about 0.01 to about 15 weight percent of the optical material. Emission stabilizers are discussed above. Preferred emission stabilizers include K₂DP (also referred to herein as KDP) and TOPO. Additional information relating to emission stabilizers and examples of other emission stabilizers and amounts thereof for use with quantum dots are described in U.S. Publication No. 20150021521 A1, published 22 Jan. 2015, of Nick, et al., entitled “Quantum Dot-Containing Compositions Including An Emission Stabilizer, Products Including Same, and Method”, which is hereby incorporated herein by reference.

An optical material can further include a rheology modifier. A rheology modifier can comprise a combination of two or more rheology modifiers. A rheology modifier can be included in the optical material in an amount from about 5 to about 12 weight percent of the optical material. Other amounts outside this range may also be determined to be useful or desirable. Further information concerning rheology modifiers is provided elsewhere herein.

The formulation from which an optical material is prepared can preferably include at least one of a cross-linking agent comprising an aliphatic dimethacrylate having an absorbance at 325 nm less than or equal to 0.08 and an absorbance at 345 nm less than or equal to 0.03 and an aliphatic methacrylate monomer has an absorbance at 345 nm less than or equal to O.Q1 in the absence of an inhibitor. More preferably, the optical material can include both a cross-linking agent comprising an aliphatic dimethacrylate, which preferably has an absorbance at 325 nm less than or equal to 0.08 and an absorbance at 345 nm less than or equal to 0.03 and an aliphatic methacrylate monomer has an absorbance at 345 nm less than or equal to 0.01 in the absence of an inhibitor.

Inclusion of the cross-linking agent in an amount in a range from about 6 to about 8 mole percent based on the moles of the cross-linking agent and monomer can also be advantageous as seen in the Examples below.

Preferably, the formulation is polymerized by exposing the formulation to light energy (e.g., UV light) to polymerize the photopolymerizable precursor monomer in which the other components are distributed or dispersed. Preferably, the other components included in the formulation are uniformly or substantially uniformly dispersed in the resulting polymer host material.

In accordance with a still further aspect of the present invention, there is provided an optical component comprising an optically transparent structure including an optical material taught herein.

Optical components and an optically transparent structure included in an optical component can have a variety of different shapes or configurations. The shape or configuration will typically be selected based on the end-use application in which the optical component is to be used. For example, an optical component and an optically transparent structure can be planar, curved, convex, concave, hollow, linear, circular, square, rectangular, oval, spherical, cylindrical, or any other shape or configuration that is appropriate based on the intended end-use application and design. Examples of preferred optically transparent structures for inclusion in backlighting units for displays include a substrate such as a planar structure or a tubular-like structure.

For example, for an optically transparent structure with a planar structure, the formulation can be disposed on or over a surface thereof. Optionally, other materials, layers, films, features, or other elements may be interposed between the formulation and the surface. For an example of an optically transparent structure including a cavity (e.g., with a tubular-like structure), the formulation can be included in the cavity.

Preferably the formulation is positioned on, over, or within a cavity in an optical structure prior to being polymerized to form an optical material.

For example, an optical component can include an optically transparent substrate having a surface on or over which the formulation or optical material is disposed. An optical component can alternatively include a formulation or optical material that is at least partially encapsulated between opposing substrates, wherein one or both of the substrates are optically transparent. Depending on the end-use application, it can be preferred to have the formulation or optical material fully encapsulated between opposing substrates that are sealed together by a seal. Examples of materials from which the substrates can be constructed include glass and optically transparent polymeric materials or films. A seal can comprise an edge or perimeter seal. A seal can preferably comprise barrier material. A barrier material can be selected to provide a barrier to oxygen, water, or both. In certain embodiments, the seal is substantially impervious to water and/or oxygen.

In another example, an optical component can comprise a formulation or optical material composition included within an optically transparent structure. For example, the formulation or optical material can be included in a hollow or cavity portion of a structure (e.g., a tube, hollow capillary, hollow fiber, other shaped vessel or container, etc.) that can be open at either or both ends. Preferably open end(s) of the member are hermetically sealed after the formulation or optical material is included therein. Examples of sealing techniques for a tubular-shaped structure include but are not limited to, (1) contacting an open end of a tube with an epoxy, (2) drawing the epoxy into the open end due to shrinkage action of a curing resin, or (3) covering the open end with a glass adhering metal such as a glass adhering solder or other glass adhering material, (4) hot glue; and (5) melting the open end by heating the glass above the melting point of the glass and pinching the walls together to close the opening to form a molten glass hermetic seal.

Other suitable techniques can be used for sealing the ends or edges of a capillary or other tube-like structures.

Other designs, configurations, and combinations of barrier materials and/or structures comprising barrier materials can be included in an optical component in which the formulation or optical material is at least partially encapsulated. Such designs, configurations, and combinations can be selected based on the intended end-use application and design. Techniques for sealing structures having other shapes or configurations will be selected based upon the particular shape or configuration.

A formulation is preferably polymerized to form an optical material after the formulation is disposed in the optically transparent structure or on or over a surface thereof.

An optically transparent structure permits light to pass into and/or out of the optical material that it may encapsulate.

The configuration and dimensions of an optical component will typically be selected based on the intended end-use application and design.

An optical component comprising an optically transparent structure in which the formulation or optical material is hermetically contained can be preferred.

An optical component can further include one or more barrier materials which can be selected to protect the formulation or optical material from environmental effects (e.g., oxygen and/or water) which may be detrimental for a given end-use application.

In accordance with yet another aspect of the present invention, there is provided a method for improving the lumen maintenance of an optical material comprising an aliphatic methacrylate polymer, the method comprising: preparing a formulation comprising: a photopolymerizable host precursor material including a monomer comprising an aliphatic methacrylate monomer and a cross-linking agent, wherein the cross-linking agent is included in the photopolymerizable host precursor material in an amount from about 5 to about 13 mole percent based on the moles of cross-linking agent and monomer, the photopolymerizable host precursor material being included in the formulation in an amount of at least 50 weight percent of the formulation; and a photoluminescent material comprising quantum dots, the photoluminescent being included in the formulation in an amount from about 0.01 to about 15 weight percent of the formulation; wherein at least one of: (a) the aliphatic dimethacrylate has an absorbance at 325 nm less than or equal to 0.08 and an absorbance at 345 nm less than or equal to 0.03, and (b) the aliphatic methacrylate monomer has an absorbance at 345 nm less than or equal to 0.01 in the absence of an inhibitor, and polymerizing the formulation to form the optical material having improved lumen maintenance.

The method can further comprise including the formulation included in an optical component including an optically transparent structure prior to polymerizing the formulation.

In accordance with a still further aspect of the present invention, there is provided a method for reducing the occurrence of visible voids in an optical material including an aliphatic methacrylate polymer and quantum dots after exposure to a temperature of −30° C. for 1000 hours, the method comprising: polymerizing a formulation comprising: a photopolymerizable host precursor material including a monomer comprising an aliphatic methacrylate monomer and a cross-linking agent, wherein the cross-linking agent is included in the photopolymerizable host precursor material in an amount from about 5 to about 13 mole percent based on the moles of cross-linking agent and monomer, the photopolymerizable host precursor material being included in the formulation in an amount of at least 50 weight percent of the formulation; and a photoluminescent material comprising quantum dots, the photoluminescent being included in the formulation in an amount from about 0.01 to about 15 weight percent of the formulation, wherein at least one of: the aliphatic dimethacrylate has an absorbance at 325 nm less than or equal to 0.08 and an absorbance at 345 nm less than or equal to 0.03, and (b) the aliphatic methacrylate monomer has an absorbance at 345 nm less than or equal to 0.01 in the absence of an inhibitor; and polymerizing the formulation.
The method can provide an optical material that has reduced occurrence of visible voids within 7
days after exposure to a temperature −30° C. for 1000 hours.

The method can further comprise including the formulation in an optical component including an optically transparent structure prior to polymerizing the formulation.

In accordance with a still further aspect of the present invention, there is provided a method for reducing the occurrence of visible voids in an optical material including an aliphatic methacrylate polymer and quantum dots contained within a sealed optically transparent structure after exposure of the sealed structure to a temperature of −30° C. for 1000 hours, the method comprising: polymerizing a formulation comprising: a photopolymerizable host precursor material including a monomer comprising an aliphatic methacrylate monomer and a cross-linking agent, wherein the cross-linking agent is included in the photopolymerizable host precursor material in an amount from about 5 to about 13 mole percent based on the moles of cross-linking agent and monomer, the photopolymerizable host precursor material being included in the formulation in an amount of at least 50 weight percent of the formulation; and a photoluminescent material comprising quantum dots, the photoluminescent being included in the formulation in an amount from about 0.01 to about 15 weight percent of the formulation, \wherein at least one of: the aliphatic dimethacrylate has an absorbance at 325 nm less than or equal to 0.08 and an absorbance at 345 nm less than or equal to 0.03, and (b) the aliphatic methacrylate monomer has an absorbance at 345 nm less than or equal to 0.01 in the absence of an inhibitor; and polymerizing the formulation.

The method can provide an optical component including an optical material that has reduced occurrence of visible voids within 7 days after exposure to a temperature −30° C. for 1000 hours.

In accordance with another aspect of the present invention, there is provided a method for forming an optical material comprising an aliphatic methacrylate polymer and a photoluminescent material comprising quantum dots with improved ductility, the method comprising: preparing a formulation comprising: a photopolymerizable host precursor material including a monomer comprising an aliphatic methacrylate monomer and a cross-linking agent, wherein the cross-linking agent is included in the photopolymerizable host precursor material in an amount from about 5 to about 13 mole percent based on the moles of cross-linking agent and monomer, the photopolymerizable host precursor material being included in the formulation in an amount of at least 50 weight percent of the formulation, the photoluminescent material comprising quantum dots, the photoluminescent being included in the formulation in an amount from about 0.01 to about 15 weight percent of the formulation, wherein at least one of: (a) the aliphatic dimethacrylate has an absorbance at 325 nm less than or equal to 0.08 and an absorbance at 345 nm less than or equal to 0.03, and (b) the aliphatic methacrylate monomer has an absorbance at 345 nm less than or equal to 0.01 in the absence of an inhibitor, and polymerizing the formulation to form the optical material whereby improved ductility is demonstrated by the optical material exhibiting fewer visible voids having a size>0.5 mm within 7 days after exposure to a temperature −30° C. for 1000 hours compared to a comparative optical material prepared from a comparative formulation that is the same in all respects except that it includes a cross-linking agent content in an amount in a range of about 13-14 mole percent based on the moles of cross-linking agent and monomer and the comparative formulation does not include at least one of (a) and (b) after exposure to a temperature −30° C. for 1000 hours.

The formulation can further include any one or more of the other ingredients (e.g., scattering particles, rheology modifiers, emission stabilizes, photoinitiators) included in a formulation within the scope of the present invention. Any one or more other aspects of a formulation within the scope of the present invention described herein (e.g., concentrations, processing steps, etc.) can also useful in this and the other methods described herein that include a formulation.

Additional aspects of the present invention include a light-emitting device comprising a light-emitting element and an optical material arranged to receive and convert at least a portion of light emitted by the light emitting element from a first emission wavelength to one or more predetermined wavelengths, wherein the optical material includes an optical material within the scope of the present invention.

In certain embodiments, the optical material can encapsulate at least the light emitting-surface of the light-emitting element. In certain embodiments, the optical material can be spaced from the light emitting-surface of the light-emitting element.

Additional aspects of the present invention also include a display including a backlighting unit including a plurality of light-emitting diodes and an optical material arranged to receive and convert at least a portion of light emitted by at least a portion of the light-emitting diodes from a first emission wavelength to one or more predetermined wavelengths, wherein the optical material includes an optical material within the scope of the present invention.

In certain embodiments, the display comprises a liquid crystal display.

Additional aspects of the present invention include a light-emitting device comprising a light-emitting element and an optical component arranged to receive and convert at least a portion of light emitted by the light emitting element from a first emission wavelength to one or more predetermined wavelengths, wherein the optical component includes an optical component within the scope of the present invention.

In certain embodiments, the optical material is hermetically sealed within the optically transparent structure. In certain embodiments, the optical component can be spaced from the light emitting-surface of the light-emitting element.

Additional aspects of the present invention also include a display including a backlighting unit including a plurality of light-emitting diodes and an optical component arranged to receive and convert at least a portion of light emitted by at least a portion of the light-emitting diodes from a first emission wavelength to one or more predetermined wavelengths, wherein the optical component includes an optical component within the scope of the present invention.

In certain embodiments, the optical material is hermetically sealed within the optically transparent structure. In certain embodiments, the optical component can be spaced from the light emitting-surface of the light-emitting element.

In certain embodiments, the display comprises a liquid crystal display.

Formulations, optical materials, optical components, light-emitting devices, and displays within the scope of the present invention may be incorporated into a wide variety of other consumer products, including flat panel displays, computer monitors, all-in-one computers, notebooks, tablets, televisions, billboards, lights for interior or exterior illumination and/or signaling, heads up displays, fully transparent displays, flexible displays, laser printers, telephones, cell phones, smartphones, personal digital assistants (PDAs), laptop computers, digital cameras, camcorders, viewfinders, micro-displays, vehicles, a large area wall, theater or stadium screen, a sign, lamps and various solid state lighting devices.

The present invention will be further clarified by the following examples, which are intended to be exemplary of the present invention.

### Example I

### Quantum Dot Preparation

### Example IA

### Red Light Emitting Quantum Dots

Synthesis of CdSe Cores:

A 1 L glass reactor was charged with 243 milliliter (mL) of 1-octadecene (ODE), 13 grams (g) trioctylphosphine oxide (TOPO), and 1.6 g octadecylphosphonic acid (ODPA) and degassed at 110° C. for 15 minutes under vacuum. The reactor was then backfilled with nitrogen (N₂) and the temperature set to 270° C. Meanwhile, six 60 mL syringes were loaded with 161 mL of cadmium oleate (Cd-oleate) in trioctylphosphine (TOP) (1 Molar (M) concentration (cone.)) solution in 161 mL of ODE, and another six 60 mL syringes were loaded with 145 mL of di-iso-butylphosphine selenide (DiBP-Se) in TOP (1 M cone.) solution in 177 mL ODE. Once the reaction mixture reached 240° C., the Cd oleate and DiBP-Se solutions were infused into the reactor at a rate of 15.8 mL/hour (hr). After 0.5 mL was infused into the reaction vessel, an additional 4.78 mL of Cd-oleate in TOP in 14.35 mL of ODE and 3.73 mL DiBP-Se in TOP in 11.19 mL ODE were injected into the reaction mixture, followed by a temperature quenching injection of 103 mL ODE. After 15 minutes, the infusion rate of Cd-oleate and DiBP-Se solutions was increased to 31.6 mL/hr. Every 10 minutes after that, the reaction rate was steadily increased to 31.6, 47.3, 63.1, and 84.2 mL/hr, respectively. After a total of 58 minutes reaction time from the time of initial infusion, the infusions were stopped and the reaction vessel cooled by subjecting the reaction vessel to a stream of cool air. This reaction was repeated an additional two times, and the material collected from the three reactions combined for use in a subsequent shelling reaction.

Synthesis of CdSe/ZnS/CdZnS Core-Shell Nanocrystals:

904 mL of the CdSe core above with a first absorbance peak at 580 nm was mixed in a clean, dry 5 L reaction vessel under nitrogen pressure with 1-octadecene (863 mL), and Zn(Oleate) (0.5 M in TOP, 274 mL). The reaction vessel was heated to 110° C. and then vacuum was applied for 15 min. The reaction vessel was then back-filled with nitrogen and heated to 350° C. The temperature was ramped, between 1° C./5 seconds and 1° C./15 seconds. Once the vessel reached 320° C., 1-dodecanethiol (246 mL) was swiftly injected and a timer started. Once the timer reached 1.5 min., one syringe containing zinc oleate (0.5 M in TOP, 281 mL) and cadmium oleate (1 M in TOP, 798 mL), and another syringe containing octanethiol (393 mL) were infused over 15 minutes. Once the timer reached 17 min., the mixture was heated at 325° C. for an additional 18 minutes. When the timer reached 35 minutes, the heating mantle was dropped and the reaction cooled by subjecting the vessel to cool air flow. The final material was precipitated via the addition of butanol and methanol (4:1 ratio), centrifuged at 3000 RCF for 5 min, and the pellet redispersed into hexanes. The sample is then precipitated once more via the addition of butanol and methanol (3:1 ratio), centrifuged, and dispersed into toluene for storage (363 g of core/shell material, 626 nm emission, 26 nm FWHM, and 94% external quantum efficiency (EQE) in film).

### Example IB

### Green Light Emitting

### Quantum Dots

Synthesis of CdSe Cores:

The following were added to a 1 L stainless steel reaction vessel: trioctylphosphine oxide (TOPO: 44.35 g), 1-octadecene (ODE: 183 mL), octadecylphosphonic acid (ODPA: 28.28 g), and cadmium oleate (I M solution in trioctylphosphine (TOP), 84.56 mL). The reactor was subjected to vacuum at 110° C. for 45 minutes, during which the temperature was raised to 270° C. under nitrogen. At 270° C., the temperature controller was set to 240° C. and 66 mL of a I M DiBP-Se in 1-dodecyl-2-pyrrolidinone (NDP) solution was rapidly injected, followed by injection of 69 mL of ODE to rapidly drop the temperature to about 230° C. Immediately following the ODE quench, an infusion of 180 mL of 0.5 M cadmium oleate in trioctylphosphine (TOP) (diluted with 180 mL of ODE) and 144 mL of 1 M DiBP-Se in NDP (diluted with 216 mL of ODE) was continuously introduced into the reaction vessel over 6 minutes at a rate of 8.29 mL/min. The reaction mixture was then rapidly cooled with a slurry of squalane and liquid nitrogen. The first excitonic absorption feature of the core materials was 476 nm. The core solution was used without further purification to make core-shell materials.

Synthesis of CdSe/ZnS/CdZnS QDs:

A 5 L reactor was charged with 772 mL of zinc oleate solution (0.5 M in TOP) and then vacuum was applied to the reactor. The reaction vessel was then heated to 100° C. and vacuum applied for 10 minutes. The reaction vessel was back-filled with nitrogen and the temperature controller set to 390° C. Once the temperature reached 320° C., an infusion of 358 mL green core from above and 339 mL 1-dodecanethiol into the reaction vessel was started and allowed to continue for 56 minutes. Once the temperature reached 300° C., a secondary infusion of 1771 mL Zn-oleate solution (0.5 M in TOP) and 590 mL Cd-oleate solution (1 M in TOP) was started and continued for 40 minutes. The reaction was then heated to 335° C. after 10 minutes. After the completion of this infusion, the reaction was allowed to heat at 330° C. for an additional 6 minutes before being quenched and cooled. Quantum dots were precipitated by the addition of butanol and methanol (4:1 ratio) and then redispersed into toluene for storage (63.6 g of core/shell material). The core-shell materials had an emission maximum of 522 nm, 28 nm FWHM and a film EQE of 99%.

### Example II

### Formulation Sample

### Preparation

Test samples were prepared generally in accordance with the following procedure. The ingredients and amounts of ingredients in grams included in the various samples are set forth in Table 1 below. The red quantum dots included in the samples described in this Example II were prepared generally as set forth in Example IA above. The green quantum dots included in the samples described in this Example II were prepared generally as set forth in Example IB above.

Following Table 1 lists the composition of formulation samples A through G.

TABLE 1
Compositions of Formulations A-G

| | Designation In The Figures For Test Samples Corresponding to the Listed Examnles | | | | | | |
|---|---|---|---|---|---|---|---|
| | A | B | | | E | F | |
| | Example !IA | Example 118 | C | D | Example !IE | Example l!F | G |
| | (Control, | (Control, | Example !IC | Example !ID | (standard | (standard | Example llG |
| | clean raws, | standard raws, | (clean raws, | (clean raws, | raws, 10.42 | raws, 7.5 | (standard |
| | 13.34 molo/o | 13.34 molo/o | 10.42 mo/% | 7.5 molo/o | molo/o cross- | mo/% cross- | raws, 5 |
| | cross-linking | cross-linking | cross-linking | cross-linking | linking | linking | molo/o cross- |
| | agent, | agent, | agent, | agent, | agent, | agent, | linking agent, |
| | 53WOl82) | 53L00179) | 53LOOl83) | 53L00185) | 53L00180) | 53W0178) | 53L00156) |
| Ingredient | (grams ) | (grams) | (grams) | (grams) | (grams) | (grams) | (grams) |

Premix Formulation

| | | | | | | | |
|---|---|---|---|---|---|---|---|
| Titanium Oxide | 45 | 45 | 45 | 45 | 45 | 45 | 45 |
| Fumed Silica | 1825 | 1820 | 1825 | 1825 | 1825 | 1825 | 1795 |
| Stabilizer - TOPO | 1593 | 1593 | 1593 | 1593 | 1593 | 1593 | 1590 |
| Stabilizer - KDP | 159 | 159 | 159 | 159 | 159 | 159 | 159 |
| Cross-linking agent | 4485 (13.34 | 4485 (13.29 | 3540 (10.4 | 2570 (7.5 | 3540 (10.4 | 2570 (7.5 | 1740 (5.0 |
| | molo/o) | molo/o) | molo/o) | molo/o) | molo/o) | molo/o) | molo/o) |
| Monomer | 21880 | 22000 | 22845 | 23805 | 22865 | 23795 | 24800 |
| Total | 29987 | 30102 | 30007 | 29997 | 30027 | 29987 | 30129 |

Matrix Formulation

| | | | | | | | |
|---|---|---|---|---|---|---|---|
| Premix Used | 19515 | 19875 | 19500 | 19530 | 18585 | 19920 | 28945 |
| Green Quantum Dots | 333.54 | 350.65 | 347.41 | 349.81 | 345.46 | 351.67 | 467.48 |
| Red Quantum Dots | 81.51 | 82.81 | 81.42 | 81.55 | 81.80 | 83.00 | 106.34 |
| Photosensitizer | 210.53 | 215.04 | 212.64 | 215.48 | 212.25 | 210.64 | 315.98 |
| Total | 20140.58 | 20523.5 | 20141.47 | 20176.84 | 20224.51 | 20565.31 | 29834.8 |
| Weight percent | 14.5 | 14.4 | 11.4 | 8.3 | 11.4 | 8.3 | 5.6 |
| cross-linking agent | | | | | | | |
| based on weight of | | | | | | | |
| total formulation | | | | | | | |

### Preparation of Formulations of Table 1

As used in Table 1, “Stabilizer” is a short-hand reference to an emission stabilizer; KDP and K₂DP refer to dipotassium lauryl phosphate and TOPO refers to tri-octyl phosphine oxide.

A clean Ross planetary homogenizing mixer was chilled to 10° C. then charged with lauryl methacrylate monomer (LMA) at the appropriate loading for the particular example, 1,12-dodecanediol dimethacrylate (D3DMA) at the appropriate loading for the particular example, titanium dioxide (R-902+, DuPont Corp.), dipotassium lauryl phosphate (KDP), and trioctylphosphine oxide (TOPO). After mixing these materials for 5 minutes, the mixer was further charged with treated fumed silica (TS-720, Cabot Corp.). This mixture was subjected to shearing for 90 minutes, then filtered through a 200 um sock mesh filter and transferred into 20 liter stainless steel storage canisters.

“Clean raws” in Table 1 refers to an aliphatic methacrylate monomer ingredient (or raw material) or an aliphatic dimethacrylate ingredient (or raw material) that has undergone adsorptive purification treatment to achieve an absorbance that does not exceed the below-stated Maximum for the particular raw material at the specified wavelength(s), as set forth in Table 2 below. In the case of an aliphatic methacrylate monomer (e.g., the lauryl methacrylate monomer) (that does not include a polymerization inhibitor), this is a maximum absorption of 0.01 absorption units at 345 nm, and for an aliphatic dimethacrylate (e.g., methyl dimethacrylate) cross-linking agent this is 0.08 absorption units at 325 nm and 0.03 absorption units at 325 nm.

TABLE 2
Table 2. Purity Criteria for Aliphatic Methacrylate Monomer and Aliphatic Methacrylate
Monomer based on absorption specification at specified wavelengths.

| | Aliphatic Methacrylate Monomer | | | | Aliphatic dimethacrylate | | |
|---|---|---|---|---|---|---|---|
| | | Measured, | Measured, | | | Measured, for | |
| | | samples IIA, | samples | | | samples IIA, | |
| | | IIB, IIC | IIH, IIJ | Measured, | | IIB, UC, UH, | Measured, |
| | | (lot: | (lot: 863- | lab purified | | IIJ (lot: | lab purified |
| Wavelength | Maximum | 15CP2974) | 01) | material | Maximum | 15CP2975) | material |
| 345 nm | 0.01 | 0.00 | 0.00 | 0.005 | 0.03 | 0.000 | 0.030 |
| 325 nm | — | — | — | — | 0.08 | 0.012 | 0.073 |

Following Table 3 lists the composition of formulation samples H and J.

TABLE 3
Composition of Formulations H & J

| | Designation In The Figures For Test Samples | |
|---|---|---|
| | Corresponding to the Listed Examples | |
| | H | J |
| | Example l!H (Control, | Example JIJ |
| | 13.34 mo/% cross- | (7.5 mo/% |
| | linking agent, 329-112- | cross-linking agent, |
| | 3) | 329-112-4) |
| Ingredient | (grams) | (grams) |

Matrix Formulation

| | | |
|---|---|---|
| Titanium Oxide | 0.12 | 0.15 |
| Fumed Silica | 4.8 | 6 |
| Stabilizer - TOPO | 4.197 | 5.246 |
| Stabilizer - KDP | 0.42 | 0.525 |
| Cross-linking agent | 11.83 | 8.47 |
| | (13.34 molo/o) | (7.5 molo/o) |
| Monomer | 57.77 | 78.53 |
| Green Quantum Dots | 0.072 | 0.090 |
| Red Quantum Dots | 0.064 | 0.080 |
| Toluene | 0.785 | 0.981 |
| Total | 80.64 | 100.07 |

Final ink

| | | |
|---|---|---|
| Matrix used | 65.25 | 65.05 |
| Photosensitizer | 0.71 | 0.7 |
| Total | 65.96 | 65.75 |
| Weight percent cross- | 14.6 | 8.4 |
| linking agent based | | |
| on weight of total | | |
| formulation | | |

### Preparation of Formulations of Table 3

As used in Table 3, “Stabilizer” is a short-hand reference to an emission stabilizer; KDP and K2DP refer to dipotassium lauryl phosphate and TOPO refers to tri-octyl phosphine oxide.

A clean, dry 200 mL Schlenk flask was charged with, lauryl methacrylate (LMA) at the appropriate loading for the particular example, dodecanediol diacrylate (D3DMA) at the appropriate loading for the particular example, fumed silica (TS-720, Cabot Corp.), titanium dioxide (R-902+, DuPont Corp.), dipotassium lauryl phosphate, and TOPO. The mixture is dispersed using an IKA Ulta-Turrax disperser for three 5 minute cycles interspersed with 5 minute rest periods, with temperature of the mixture controlled by placing the flask in a water bath. The flask is then charged with 2 weight percent toluene, a magnetic stirbar, and a rubber septum and the solution inserted and subjected to azeotropic drying by using a vacuum manifold and degassed via three vacuum-nitrogen backfill cycles. The flask is then charged with a green quantum dot solution dot in toluene, then a red quantum dot solution in toluene, then transferred into glovebox where additional toluene is added to the mixture. The mixture is then transferred to an amber bottle and stored at 10° C.

### Example III

### Preparation of Optical Components

Optical components were prepared with formulations described in the above Tables 1 and 3. Test data for an optical component prepared with a particular formulation is labeled by the Sample designation of the particular formulation in the Figures. Each optical component included a glass capillary prepared generally as described below utilizing a formulation having a composition of one of the above Examples. The capillaries were borosilicate glass capillaries having the following dimensions: 4 mm wide by 1 mm height OD (3.3 mm×0.3 mm ID) by 700 mm length.

A capillary was placed into a gasketed fill head to make a gastight seal with the fill head. The capillary was then inerted by evacuating the capillary to <100 mtorr and repressurizing the capillary with nitrogen. The pump/refill procedure was repeated an additional two times to complete inerting of the capillary. Once inerted, the capillary was once again evacuated to <100 mtorr. At this time, a separate valve in the fill head is opened to admit the into the capillary. The level of ink in the capillary is controlled by the fill time. (A formulation may also be referred to as a QD containing matrix or as an ink in the Examples.)

When the required level of ink has entered the capillary, the ink valve closes and nitrogen pressure valve is opened, pushing the ink into the bottom of the capillary and maintaining inert conditions.

After filling, the optics were cured by exposure to a high output TS fluorescent bulb for 96 seconds (examples of other times in the range 90-150 seconds can also be useful, other times outside this range may also be determined by the skilled artisan to be useful) having a light intensity of 4 mW/cm² (range 3.5-4.5) at a distance less than 80 mm from the bulb (examples of other distances in the range 40-80 mm can also be useful, other distances outside this range may also be determined by the skilled artisan to be useful). Following this “soft” cure, the optics were cured more aggressively using a Dymax “D” type metal halide bulb with an energy of 2400 mJ/cm² (examples of other energies in the range 1800-3200 J/cm² can also be useful; other energies outside this range may also be determined by the skilled artisan to be useful).

### Example 4

### Optical Component Testing of a First Set of Test Capillaries A Through G Under 445 nm Blue LEDs at 10 W/cm² Flux Condition and 105° C. Thermal Condition

The setup includes a blue LED with peak wavelength of 445 nm. A test capillary is subjected to a blue light flux of −10 W/cm² flux conditions and 105° C. thermal condition.

The emission spectra of a test optical component (prepared generally as described above with the formulation corresponding to the sample designation) was captured prior to the start of the blue light exposure. This is done by exciting the quantum dots in the composition with a 445 nm blue light source and measuring the resultant spectra in a half moon integrating sphere. The performance of the test capillary was monitored during the period of exposure to the 445 nm blue light flux in the above-described set up. The change in performance of quantum dots in the test capillary is tracked periodically by measuring the resultant lumens (upon excitation with a 445 nm blue light source) in an integrating sphere.

Test capillaries for this Example 4 were prepared generally as described in Example 3 using the formulations described in Example 2 and Table 1. Test capillaries are designated by the same designation (e.g., A, B, etc.) as that corresponding formulation included therein and polymerized to form the optical material contained therein.

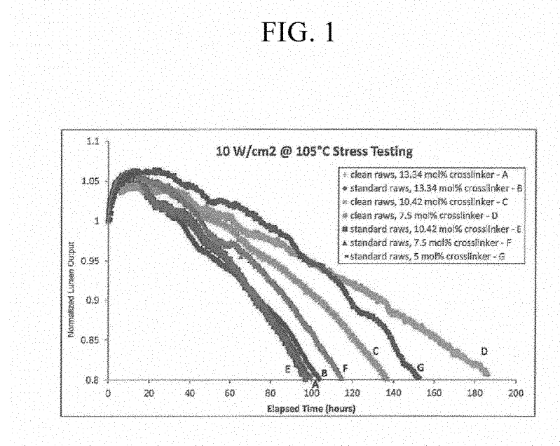

FIGS. 1-3 present data for test capillaries A-G under 445 nm blue LEDs at 10 W/cm² flux condition and 105° C. thermal condition:

Test capillaries designated A, C, and D were prepared with formulations including “clean raw” lauryl methacrylate monomer and “clean raw” D3DMA, as described above.

Test capillaries designated B, E, F, and G were prepared with formulations in which the lauryl methacrylate monomer and D3DMA did not undergo adsorptive purification treatment.
The amount of cross-linking agent in test capillaries A and B was about 13.34 mol percent.

The amount of cross-linking agent in test capillaries C and E was about 10.42 mol percent.

The amount of cross-linking agent in test capillaries D and F was about 7.5 mol percent.

The amount of cross-linking agent in test capillary G was about 5 mol percent.

The results permit a comparison of the effect of including “clean raws” in a formulation; the effect of reduced cross-linking agent amounts (compared to a formulation including a cross-linking agent amount of about 14 weight percent), and a comparison of the combined effect of including “clean raws” and reduced amount of cross-linking agent under the test conditions of this Example 4.

FIG. 1 shows the results for all of test capillaries A through G on the same graph.

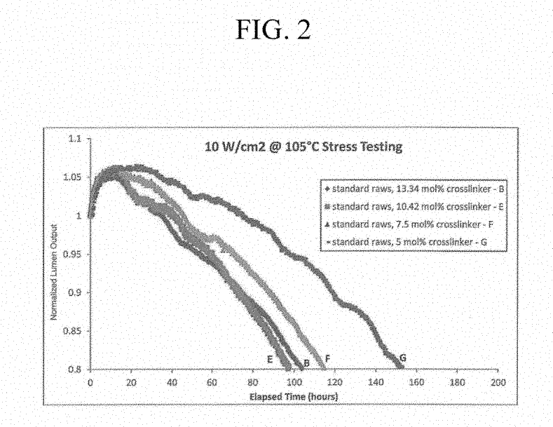

FIG. 2 shows the results for test capillaries B, E, F, and G (including an optical material prepared with formulations in which the lauryl methacrylate monomer and D3DMA did not undergo adsorptive purification treatment and different amounts of cross-linking agent).

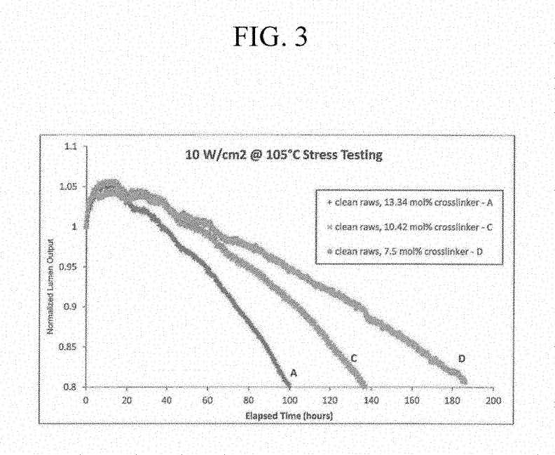

FIG. 3 shows the results for test capillaries A, C, and D (including an optical material prepared with formulations in which the lauryl methacrylate monomer and D3DMA were “clean raws” and different amounts of cross-linking agent).

FIGS. 1-3 show a drop in luminance with time for test capillaries A through G under accelerated testing at the specified high optical flux and temperature conditions.

As can be seen in FIGS. 1-3, test capillaries B, E, F, and G including optical material prepared from formulations including lauryl methacrylate monomer and D3DMA raw materials that have not undergone adsorptive purification treatment show a small improvement in L₈₀ lifetime at lower cross-linking agent levels, increasing from 98 to 115 hours. However, in the case of test capillaries A, C, and D including optical material prepared from formulations including “clean raw” lauryl methacrylate monomer and “clean raw” D3DMA, compared to the sample A (including about 14 weight percent cross-linking agent), lower cross-linking agent levels show improvements from about 100 hours to about 135 hours for sample C (including about 10 weight percent cross-linking agent), and to about 188 hours for sample D (including about 8 weight percent cross-linking agent). (L80 lifetime refers to the amount of time for the luminance to drop to 80% of the initial value.)

In FIGS. 1-3, it can be seen from the test results that cleaning of the monomer and D3DMA raw materials at the nominal 13.34% cross-linking agent loading increased lifetime under such test conditions from 105 to 140 hours. Lifetime under such test conditions did not change appreciatively for optical materials prepared from the samples that did not include the “clean raws” as cross-linking agent (also referred to as “crosslinker”) was decreased from 13.34 to 5 mol percent (%), ranging from 99-115 hours, within the reproducibility of the test. Unexpectedly, when “clean raws” were substituted, the decreasing cross-linking agent had a very appreciable beneficial effect on lifetime under the test conditions of Example 4, increasing from 100 hours to 190 hours through the decrease of D3DMA cross-linking agent from 13.34 to 7.5 mol %.

### Example S

### Optical Component Testing

### Testing of a Second Set Test Capillaries a Through F Under 445 nm Blue LEDs at 810 mW/LED Flux Condition and 97° C. Thermal Condition

The setup includes an array of blue LEDs with peak wavelength of 445 nm. A test capillary is subjected to a blue light flux of −810 mW/LED flux condition and 97° C. thermal condition. The test capillary is held at a distance of about 0.6 mm above the LED array. The temperature of the optical material (quantum dot-containing polymer matrix) at these conditions has been determined to be −97° C. This is measured by placing a 1 mil Type-T thermocouple in the matrix. The thermocouple is placed in the glass capillary prior to filling and curing the ink.

The emission spectra of a test capillary (prepared generally as described above with the formulation corresponding to the sample designation) was captured prior to the start of the blue light exposure. This is done by exciting the quantum dots in the composition with a 445 nm blue light source and measuring the resultant spectra in a half moon integrating sphere. The performance of the test capillary was monitored during the period of exposure to the 445 nm blue light flux in the above-described set up. The change in performance of quantum dots in the test capillary is tracked periodically by measuring the resultant lumens (upon excitation with a 445 nm blue light source) in an integrating sphere.

Test capillaries for this Example 5 were prepared generally as described in Example 3 using the formulations described in Example 2 and Table 1. Test capillaries are designated by the same designation (e.g., A, B, etc.) as the corresponding formulation included therein and polymerized to form the optical material contained therein.

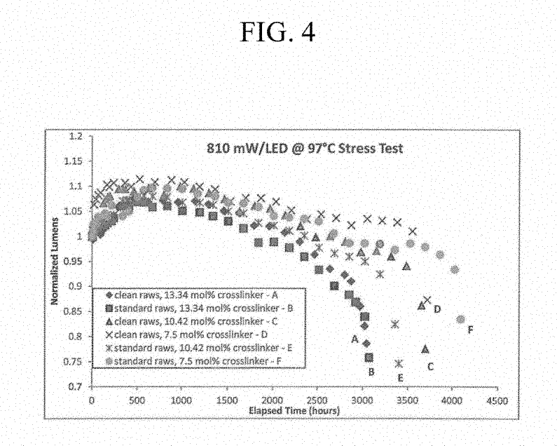

FIG. 4 presents data for test capillaries A-F under 445 nm blue LEDs at 810 mW/LED flux condition and 97° C. thermal condition.

Test capillaries designated A, C, and D were prepared with formulations including “clean raw” lauryl methacrylate monomer and “clean raw” D3DMA, as described above.

Test capillaries designated B, E, and F were prepared with formulations in which the lauryl methacrylate monomer and D3DMA did not undergo adsorptive purification treatment.

The amount of cross-linking agent in test capillaries A and B was about 13.34 mol percent (about 14 weight percent).

The amount of cross-linking agent in test capillaries C and E was about 10.42 mol percent (about 11 weight percent).

The amount of cross-linking agent in test capillaries D and F was about 7.5 mol percent (about 8 weight percent).

The results permit a comparison of the effect of including “clean raws” in a formulation; the effect of reduced cross-linking agent amounts (compared to a formulation including a cross-linking agent amount of about 14 weight percent), and a comparison of the combined effect of including “clean raws” and reduced amount of cross-linking agent under the test conditions of this Example 5.

The testing for this Example 5 is done at lower temperature and flux than that used in Example 4. At these lower stress and larger illumination fractions, the effect of reduced cross-linking agent is seen with an increase in L70 lifetime from 3000 to 4200 hours by decreasing the cross-linking agent level. (L70 lifetime refers to the amount of time for the luminance to drop to 70% of the initial value.)

Under the test conditions of this Example 5, reduction of cross-linking ng agent also shows the effect of increasing L70 lifetime from 3100 hours to 4200 hours (FIG. 4) although the additive effect of the cleaned raw materials was not apparent at the lower flux stress level of this Example 5. This was accompanied by a slowed wavelength shift in peak emission of both the red and green quantum dots as seen in FIGS. 6A and 6B.

Additional results for the test capillaries A-F of this Example 5 are shown in FIGS. 5A-C and FIG. 7.

### Example 6

### Optical Component Testing

### Of a First Set of Test Capillaries H & J Under 445 nm Blue LEDs at 10 W/cm² Flux Condition and 105° C. Thermal Condition

The setup includes an array of blue LEDs with peak wavelength of 445 nm. A test capillary is subjected to a blue light flux of −10 W/cm² flux conditions and 105° C. thermal condition.

The emission spectra of a test optical component (prepared generally as described above with the formulation corresponding to the sample designation) was captured prior to the start of the blue light exposure. This is done by exciting the quantum dots in the composition with a 445 nm blue light source and measuring the resultant spectra in a half moon integrating sphere. The performance of the test capillary was monitored during the period of exposure to the 445 nm blue light flux in the above-described set up. The change in performance of quantum dots in the test capillary is tracked periodically by measuring the resultant lumens (upon excitation with a 445 nm blue light source) in an integrating sphere.

Test capillaries for this Example 6 were prepared generally as described in Example 3 using the formulations described in Example 2 and Table 3. Test capillaries are designated by the same designation (e.g., H and J) as the corresponding formulation included therein and polymerized to form the optical material contained therein.

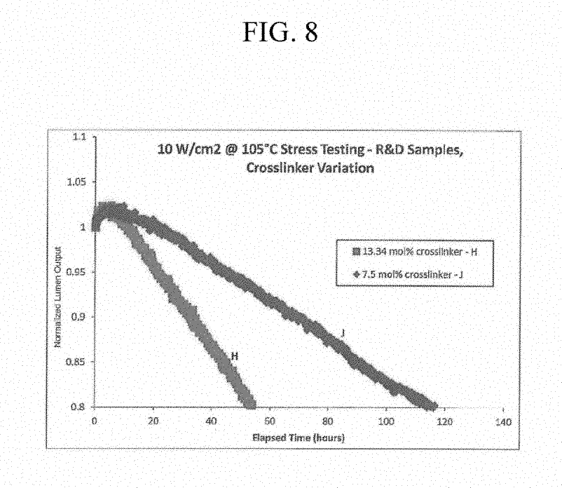

FIG. 8 presents data for test capillaries H and J under 445 nm blue LEDs at 10 W/cm² flux condition and 105° C. thermal condition.

Test capillaries H and J were prepared with formulations in which the lauryl methacrylate monomer and D3DMA did not undergo adsorptive purification treatment.

The amount of cross-linking agent in test capillary H was about 13.34 mol percent (about 14 weight percent).

The amount of cross-linking agent in test capillary J was about 7.5 mol percent (about 8 weight percent).

The results permit a comparison of the effect of a reduced cross-linking agent amount (compared to a formulation including a cross-linking agent amount of about 14 weight percent) under the test conditions of this Example 6.

FIG. 8 shows the results for test capillaries H and J on the same graph.

FIG. 8 shows a drop in luminance with time for test capillaries H and J under accelerated testing at the specified high optical flux and temperature conditions.

As can be seen in FIG. 8, test capillaries including optical material prepared from formulations including standard lauryl methacrylate monomer and standard D3DMA raw materials show an improvement in L₈₀ lifetime at a cross-linking agent level of about 8 weight percent. (L80 lifetime refers to the amount of time for the luminance to drop to 80% of the initial value.)

### Example 7

### Optical Component Testing

### Testing of a Second Set Test Capillaries H & J Under 445 nm Blue LEDs at 810 mW/LED Flux Condition and 97° C. Thermal Condition

The setup includes an array of blue LEDs with peak wavelength of 445 nm. A test capillary is subjected to a blue light flux of −810 mW/LED flux condition and 97° C. thermal condition. The test capillary is held at a distance of about 0.6 mm above the LED array. The temperature of the optical material (quantum dot-containing polymer matrix) at these conditions has been determined to be 97° C. This is measured by placing a 1 mil Type-T thermocouple in the matrix. The thermocouple is placed in the glass capillary prior to filling and curing the ink.

The emission spectra of a test capillary (prepared generally as described above with the formulation corresponding to the sample designation) was captured prior to the start of the blue light exposure. This is done by exciting the quantum dots in the composition with a 445 nm blue light source and measuring the resultant spectra in a half moon integrating sphere. The performance of the test capillary was monitored during the period of exposure to the 445 nm blue light flux in the above-described set up. The change in performance of quantum dots in the test capillary is tracked periodically by measuring the resultant lumens (upon excitation with a 445 nm blue light source) in an integrating sphere.

Test capillaries H and J were prepared with formulations in which the lauryl methacrylate monomer and D3DMA did not undergo adsorptive purification treatment.

The amount of cross-linking agent in test capillary H was about 13.34 mol percent (about 14 weight percent).

The amount of cross-linking agent in test capillary J was about 7.S mol percent (about 8 weight percent).

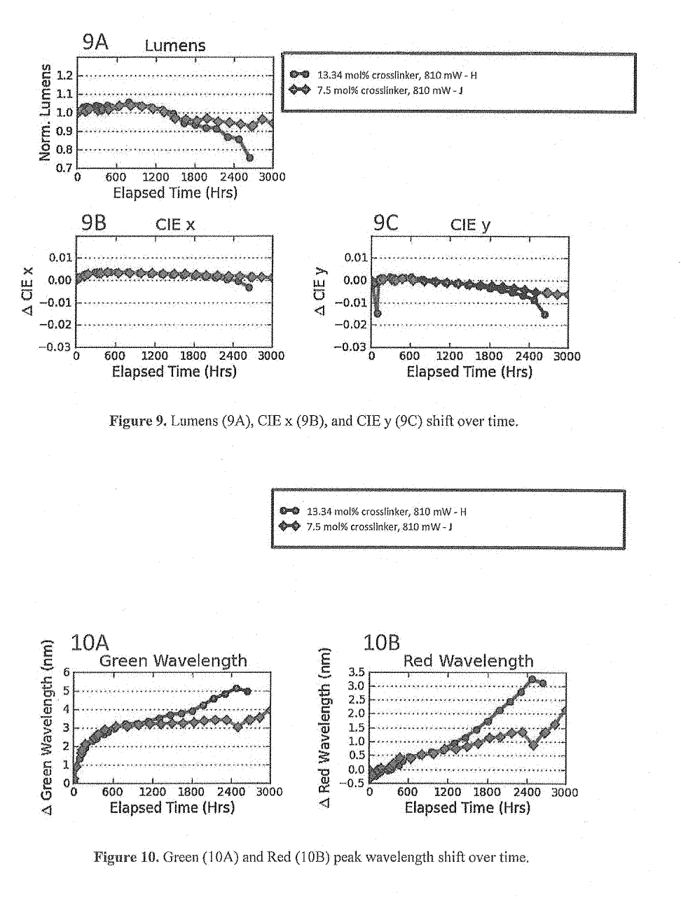

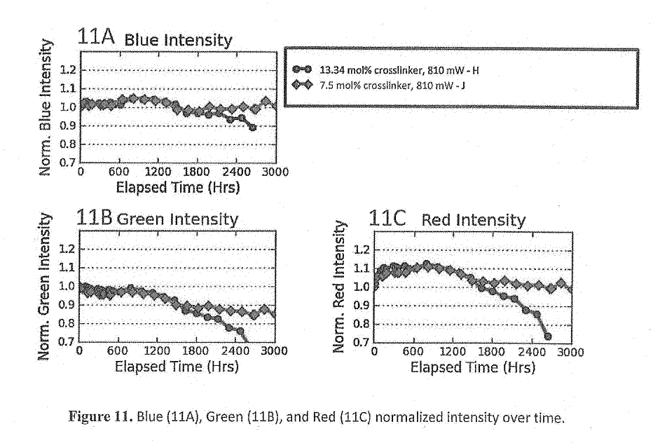

FIGS. 9-11 present data for test capillaries H and J under 44S nm blue LEDs at 810 mW/LED flux condition and 97° C. thermal condition.

A lumen maintenance improvement is expected for optical materials within the scope of the invention under less stressful conditions (e.g., under lower flux and/or lower temperature conditions).

### Example S

### Testing of Test Capillaries Made with Formulations A Through F Low Temperature Storage Test

A third set of capillaries A through G, prepared as generally described above, were collected and heated to 90° C. for one hour in an oven. After allowing to cool down to room temperature, the third set of test capillaries were placed in a freezer at −30° C. for 1000 hours. At the end of this “cold soak” period, all samples were removed and stored at room temperature for no less than 2S days, subsamples being removed on day 0 and every subsequent 7 days for visual inspection. Visual inspection consisted of counting the number or parts having a void visible to the naked eye greater than O.S mm by placing the capillary against a backlight table for inspection with a marked measurement tool.

When the test capillaries of this Example 6 were subjected to cold temperature storage testing, the lower cross-linking agent levels resulted in a lower number of voids visible to the naked eye. This effect is seen in parts cured using a soft cure step of 48 seconds and a soft cure of 96 seconds, in each case using TS bulbs. The added benefit of increasing the soft cure time with TS bulbs from 48 seconds to 96 seconds, drives the number of voids visible to the naked eye to about 0.

In accordance with yet another aspect of the present invention, there is provided a method for purifying an aliphatic dimethacrylate comprising: (a) stirring a mixture including an aliphatic dimethacrylate including at least one impurity with an activated adsorbent powder to purify the aliphatic dimethacrylate by adsorption of at least a portion the at least one impurity by the activated adsorbent powder, (b) filtering the mixture to remove the used activated adsorbent powder and collect the purified aliphatic dimethacrylate, and (c) repeating steps (a) and (b) until the collected purified aliphatic dimethacrylate has an absorbance at 325 nm less than or equal to 0.08 and an absorbance at 345 nm less than or equal to 0.03.

Use of aliphatic dimethacrylate that has been purified by iterative exposure of the material to an activated adsorbent powder or other purifying adsorbent in particulate form can reduce impurities in the material which may otherwise give rise to unwanted side effects, such as, for discoloration.

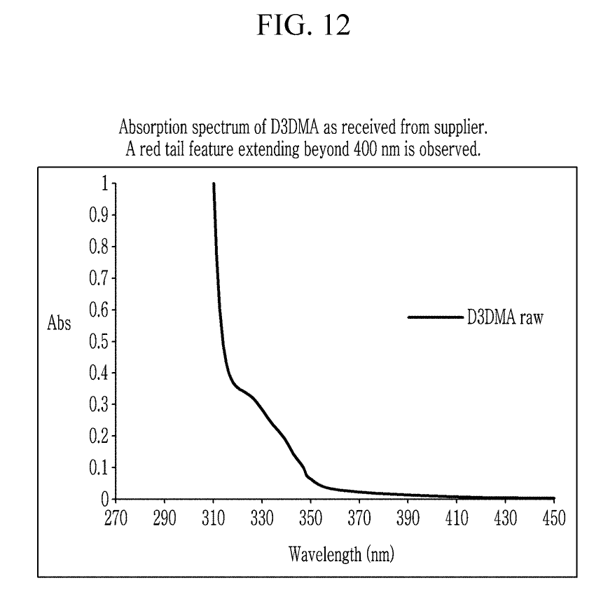

For example, the absorption spectrum of standard commercial D3DMA, as received, shows a red tail extending beyond 400 nm (See FIG. 12).

It is expected that treatment of aliphatic dimethacrylate by the present method can remove at least some of the impurity in the material that could result in discoloration of the material over extended periods of time under exposure to elevated flux and temperature conditions.

Examples of activated adsorbent powders for inclusion in the present method include alumina (e.g. activated neutral Brockmann Type I alumina), activated carbon, and an ion exchange resin in particulate form. Other suitable activated adsorbent powders can also be used.

Combinations of different activated adsorbent powders (e.g., use of a mixture including two or more different activated adsorbent powders), sequential use of different activated adsorbent powders in separate steps, or inclusion of both can also be included in the present method.

For example, the activated adsorbent powder included in the mixture in the first performance of step (a) and the activated adsorbent powder included in the mixture in a repeat performance of step (a) can have different compositions.

Preferably, the mixture includes one part aliphatic dimethacrylate to one part activated adsorbent powder.

A mixture including one gram activated adsorbent powder to 10 milliliters aliphatic dimethacrylate can also be desirable.

In certain embodiments, step (a) can comprise stirring the mixture for at least three (3) hours. Longer and shorter times can also be determined to be useful or desirable, dependent upon the time the adsorbent powder remains active.

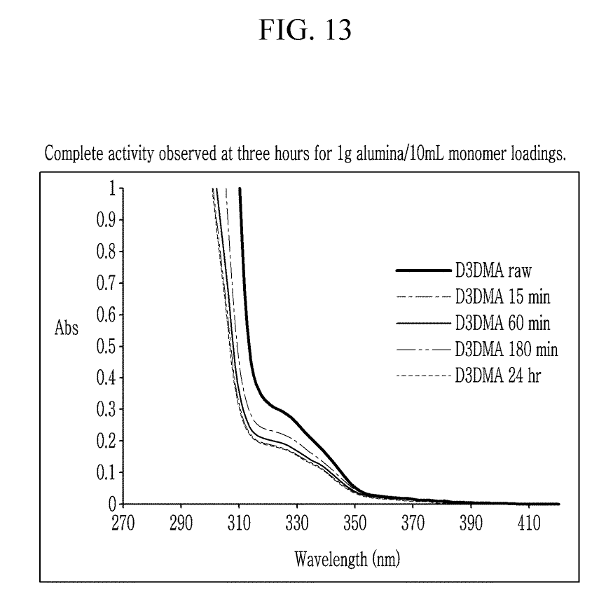

FIG. 13 provides absorbance spectra taken for standard commercial D3DMA, as received, and for mixtures of D3DMA and alumina (at a concentration of 1 g alumina/10 mL D3DMA) after 15 minutes, 60 minutes, 180 minutes and twenty-four hours.

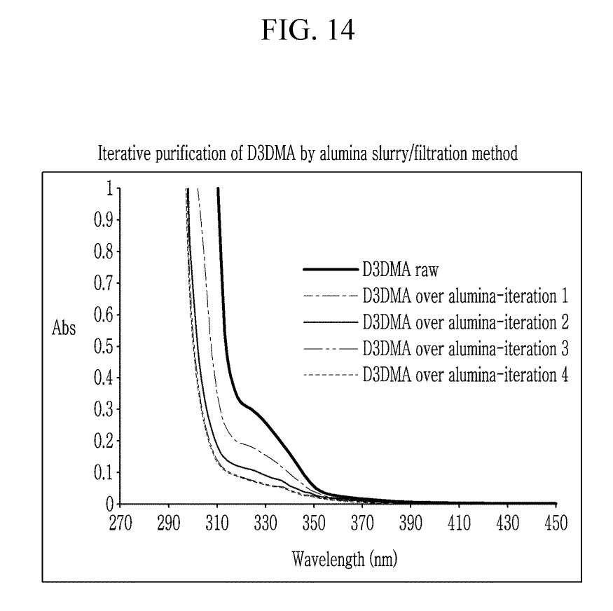

FIG. 14 provides absorbance spectra for standard commercial D3DMA, as received, and for mixtures of D3DMA and alumina (at a concentration of 1 g alumina/IO ML D3DMA) after a single performance of steps (a) and (b), two iterations of steps (a) and (b), three iterations of steps (a) and (b), and four iterations of steps (a) and (b).

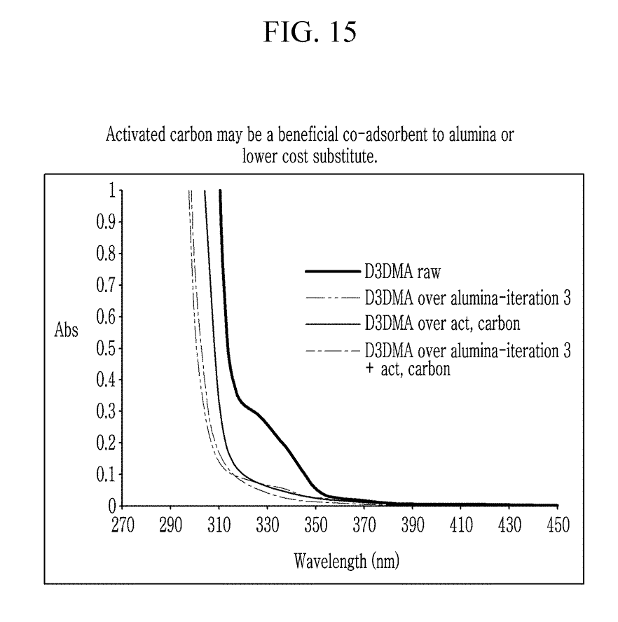

FIG. 15 provides absorbance spectra for standard commercial D3DMA, as received, and for a mixture of D3DMA and alumina (at a concentration of 1 g alumina/IO ML D3DMA) after two iterations of steps (a) and (b), for a single performance of steps (a) and (b) for a mixture of D3DMA and activated carbon, and for a mixture of D3DMA and alumina after three iterations of steps (a) and (b) followed by a fourth performance of steps (a) and (b) with a mixture including activated carbon and the D3DMA collected from the three iterations of steps (a) and (b) with alumina, and four iterations of steps (a) and (b).

In certain embodiments steps (a) and (b) can be repeated until no change is observed in the absorption spectrum of the collected purified aliphatic dimethacrylate.

A preferred embodiment of the present method includes preparing a slurry of activated neutral Brockmann Type I alumina and aliphatic dimethacrylate at loadings of 1 g alumina per 10 mL aliphatic dimethacrylate, stirring the slurry for a minimum of 3 hours (or until complete activity is observed (e.g., a spectrum with an absorbance at 325 nm less than or equal to 0.08 and an absorbance at 345 nm less than or equal to 0.03 is obtained for the treated material), and filtering the slurry, preferably over a fritted glass disc, to remove the spent alumina, and performing the step of preparing a new slurry including the collected filtrate and fresh alumina at the same loadings. This process is repeated until an absorbance spectrum including the desired features is obtained for the filtrate or until no change is observed in the absorption spectrum of the filtrate, typically 2 to 3 iterations at the aforementioned concentrations.

As discussed above, the desired purification level may be attained through the use of a combination of activate adsorbent powder or other particulate purification solid media. Activated carbon at identical or generally similar concentrations may serve at least as well as alumina and, additionally, may remove species still remaining following purification with alumina. Ion exchange resins having complementary or similar purification activity can also be used.

In accordance with yet another aspect of the present invention, there is provided a method for purifying an aliphatic methacrylate monomer comprising: (a) stirring a mixture including an aliphatic methacrylate monomer including at least one impurity with an activated adsorbent powder to purify the aliphatic methacrylate monomer by adsorption of at least a portion the at least one impurity by the activated adsorbent powder, (b) filtering the mixture to remove the used activated adsorbent powder and collect the purified aliphatic methacrylate monomer, and (c) repeating steps (a) and (b) until the aliphatic methacrylate monomer has an absorbance at 345 nm less than or equal to 0.0 I, wherein the method is carried out in the absence of a polymerization inhibitor.

Use of standard commercial aliphatic methacrylate monomer that has been purified by iterative exposure of the material to an activated adsorbent powder or other purifying adsorbent in particulate form can reduce impurities in the material which may otherwise give rise to unwanted side effects, such as, for example, discoloration.

It is expected that treatment of aliphatic methacrylate monomer by the present method can remove at least some of the impurity in the material that could result in discoloration of the material over extended periods of time under exposure to elevated flux and temperature conditions

Examples of activated adsorbent powders for inclusion in the present method include alumina (e.g. activated neutral Brockmann Type I alumina), activated carbon, and an ion exchange resin in particulate form. Other suitable activated adsorbent powders can also be used.

Combinations of different activated adsorbent powders (e.g., use of a mixture including two or more different activated adsorbent powders), sequential use of different activated adsorbent powders in separate steps, or inclusion of both can also be included in the present method.

For example, the activated adsorbent powder included in the mixture in the first performance of step (a) and the activated adsorbent powder included in the mixture in a repeat performance of step (a) can have different compositions.

Preferably, the mixture includes one part aliphatic methacrylate monomer to one part activated adsorbent powder.

A mixture including one gram activated adsorbent powder to 10 milliliters aliphatic methacrylate monomer can also be desirable.

In certain embodiments, step (a) can comprise stirring the mixture for at least three (3) hours. Longer and shorter times can also be determined to be useful or desirable, dependent upon the time the adsorbent powder remains active.

In certain embodiments steps (a) and (b) can be repeated until no change is observed in the absorption spectrum of the collected purified aliphatic methacrylate monomer.

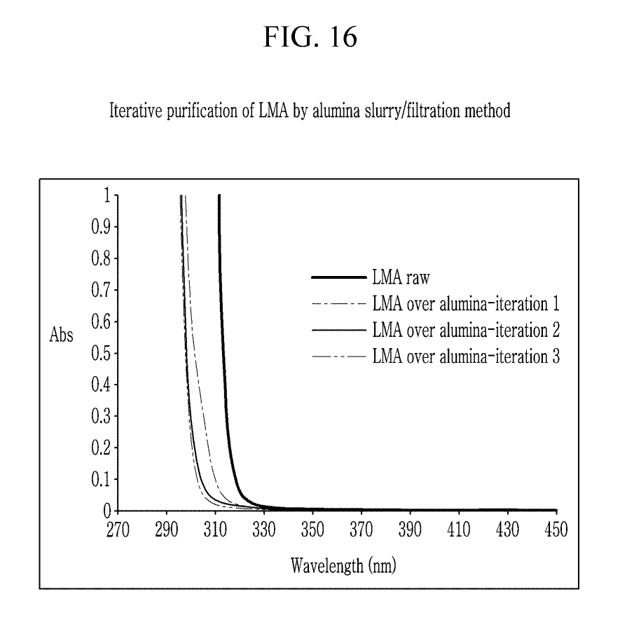

FIG. 16 provides absorbance spectra for standard commercial lauryl methacrylate monomer (LMA), as received, and for mixtures of LMA and alumina (at a concentration of 1 g alumina/IO mL LMA) after a single performance of steps (a) and (b), two iterations of steps (a) and (b), and three iterations of steps (a) and (b).

A preferred embodiment of the present method includes preparing a slurry of activated neutral Brockmann Type I alumina and aliphatic methacrylate monomer at concentrations (or loadings) of 1 g alumina per 10 mL monomer, stirring the slurry for a minimum of 3 hours (or until complete activity is observed (e.g., a spectrum with an absorbance at 345 nm less than or equal to 0.01 (in the absence of a polymerization inhibitor) is obtained for the treated material), and filtering the slurry, preferably over a fritted glass disc, to remove the spent alumina, and performing the step of preparing a new slurry including the collected filtrate and fresh alumina at the same loadings. This process is repeated until an absorbance spectrum including the desired features is obtained for the filtrate or until no change is observed in the absorption spectrum of the filtrate, typically 2 to 3 iterations at the aforementioned concentrations.

Preferably, the method is carried out for aliphatic methacrylate monomer in the absence of a polymerization inhibitor.

As discussed above, the desired purification level may be attained through the use of a combination of activate adsorbent powder or other particulate purification solid media. Activated carbon at identical concentrations may serve at least as well as alumina and, additionally, may remove species still remaining following purification with alumina. Ion exchange resins having complementary or similar purification activity can also be used.

The above purification methods for purifying aliphatic dimethacrylate and aliphatic methacrylate monomer avoid the disadvantages that can be associated with distillation methods (e.g., the risk of triggering thermal runaway reactions) and of column filtration which may result in low and undesirable yields, as a substantial quantity of adsorptive media may be needed to attain desired levels of purification, increasing the quantity of raw material left behind on the column.

Additional information that may be helpful can be found, for example, in U.S. Publication No. 20120113671 A1, published 10 May 2012, of Sadasivan, et al., entitled “Quantum Dot Based Lighting”; U.S. Publication No. 20130148376 A1, published 13 Jun. 2013, of Nick, et al., entitled “Stress-Resistant Component For Use With Quantum Dots”; U.S. Publication No. 20140027673 A1, published 30 Jan. 2014, of Nick, et al., entitled “Method of Making Components Including Quantum Dots, Methods, and Products”; U.S. Publication No. 20150009686 A 1, published 8 Jan. 2015, of Pumyea, et al., entitled “Light Mixing Chamber For Use With Light Guide Plate”; and U.S. Publication No. 20150362654 A1, published 17 Dec. 2015, of Sadasivan, et al., entitled “Light Mixing Chamber For Use With Color Converting Material and Light Guide Plate and Assembly”, each of the foregoing being hereby incorporated herein by reference in its entirety.

“Solid state external quantum efficiency” (also referred to herein as “EQE” or “solid state photoluminescent efficiency) can be measured in a 12″ integrating sphere using a NIST traceable calibrated light source, using the method developed by Mello et al., Advanced Materials 9(3):230 (1997), which is hereby incorporated by reference. Such measurements can also be made with a QEMS from Lab Sphere (which utilizes a 4 in sphere; e.g. QEMS-2000: World Wide Website laser2000.nl/upload/documenten/fop_21-en2.pdf).

As used herein, the singular forms “a”, “an” and “the” include plural unless the context clearly dictates otherwise. Thus, for example, reference to an emissive material includes reference to one or more of such materials.

Applicants specifically incorporate the entire contents of all cited references in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A formulation for use in preparing an optical material, the formulation comprising:
a photopolymerizable host precursor material including a monomer comprising an aliphatic methacrylate monomer and a cross-linking agent, wherein the cross-linking agent is included in the photopolymerizable host precursor material in an amount from about 5 to about 13 mole percent based on the moles of cross-linking agent and monomer, the photopolymerizable host precursor material being included in the formulation in an amount of at least 50 weight percent of the formulation; and
a photoluminescent material comprising quantum dots, the photoluminescent being included in the formulation in an amount from about 0.01 to about 15 weight percent of the formulation.

2. A formulation in accordance with claim 1 further comprising light scattering particles, the scattering particles being included in the formulation in an amount from about 0.01 to about 3 weight percent of the formulation.

3. A formulation in accordance with claim 1 further comprising an emission stabilizer, the emission stabilizer being included in the formulation in an amount from about 0.01 to about 15 weight percent of the formulation.

4. A formulation in accordance with claim 1 further comprising a photoinitiator, the photoinitiator being included in the formulation in an amount from about 1 to about 5 weight percent of the formulation.

5. A formulation in accordance with claim 1 further comprising a rheology modifier”, the rheology modifier being included in the formulation in an amount from about 5 to about 12 weight percent of the formulation

6. A formulation in accordance with claim 1 wherein the cross-linking agent comprises an aliphatic dimethacrylate.

7. A formulation in accordance with claim 6 wherein the aliphatic dimethacrylate has an absorbance at 325 nm less than or equal to 0.08 and an absorbance at 345 nm less than or equal to 0.03.

8. A formulation in accordance with claim 1 wherein the aliphatic methacrylate monomer has an absorbance at 345 nm less than or equal to 0.01 in the absence of an inhibitor.

9. A formulation in accordance with claim 1 wherein the amount of cross-linking agent is in a range from about 6 to about 8 mole percent.

10. An optical material comprising a formulation in accordance with claim 1 that has been polymerized.

11. An optical material in accordance with claim 10 wherein polymerization comprises curing the formulation with UV light.

12. An optical material comprising:
a host material comprising an aliphatic methacrylate polymer, the polymer being included in the composition in an amount of at least 50 weight percent of the optical material; and
a photoluminescent material comprising quantum dots included in the host material, the photoluminescent being included in the optical material in an amount from about 0.01 to about 15 weight percent of the optical material, prepared from a formulation in accordance with claim 1, wherein the optical material has improved lumen maintenance.

13-15. (canceled)

16. An optical component comprising an optically transparent structure in which an optical material in accordance with claim 10 is included.

17. An optical component in accordance with claim 16 wherein the optical material is hermetically sealed within the optically transparent structure.

18-30. (canceled)

31. A light-emitting device comprising a light-emitting element and an optical material arranged to receive and convert at least a portion of light emitted by the light emitting element from a first emission wavelength to one or more predetermined wavelengths, wherein the optical material comprises an optical material in accordance with claim 10.

32. (canceled)

33. A display comprising an optical material comprises an optical material in accordance with claim 10.

34-35. (canceled)

36. A device comprising an optical material in accordance with claim 10.

37. A light-emitting device comprising a light-emitting element and an optical component in accordance with claim 16, the optical component being arranged to receive and convert at least a
portion of light emitted by the light emitting element from a first emission wavelength to one or more predetermined wavelengths.

38. (canceled)

39. A display comprising an optical component in accordance with claim 16.

40-41. (canceled)

42. A device comprising an optical component in accordance with claim 16.

43-108. (canceled)
